(19) United States
(12) Patent Application Publication
(10) Pub. No.: US 2024/0251618 A1
(43) Pub. Date: Jul. 25, 2024

(54) DISPLAY DEVICE

(71) Applicant: Sharp Display Technology Corporation, Kameyama City, Mie (JP)

(72) Inventor: Shinzoh MURAKAMI, Kameyama City, Mie (JP)

(21) Appl. No.: 18/562,021

(22) PCT Filed: Jun. 21, 2021
(86) PCT No.: PCT/JP2021/023465

§ 371 Date: Nov. 17, 2023

(51) Int. Cl. H10K 59/131; G09G 3/3225

(52) U.S. Cl. CPC H10K 59/131; G09G 3/3225; G09G 2300/0842

(57) ABSTRACT

On a chip-mounting portion, a plurality of chip-use terminals are provided in a single row, and a plurality of terminal lines are provided extending parallel to each other in such a manner as to correspond to the plurality of chip-use terminals and being electrically connected respectively to the plurality of chip-use terminals, and a chip support body is provided between the plurality of chip-use terminals.

### TECHNICAL FIELD

The present invention relates to display devices.

### BACKGROUND ART

The organic EL display device, or the self-luminous display device built around organic electroluminescence elements (hereinafter, may be referred to the “organic EL elements”), has been attracting attention as a promising successor to the liquid crystal display device. Some flexible organic EL display devices are being proposed that include a flexible resin substrate layer carrying organic EL elements and other related components thereon.

As an example, Patent Literature 1 discloses an LSI (large scale integration)-chip-mounting, flexible wiring board that includes a distance-keeping means for keeping a minimum distance between an LSI chip and LSI-use terminals in mounting the LSI chip in an opening formed in an insulating film as a region for mounting the LSI chip.

### CITATION LIST

### Patent Literature

Patent Literature 1: Japanese Patent No. 3914478

### SUMMARY OF INVENTION

### Technical Problem

Meanwhile, in the LSI-chip-mounting, flexible wiring board disclosed in Patent Literature 1 listed above, although the distance-keeping means allows for restraining of warping of the flexible wiring board, the conductive particles contained in an anisotropic conductive film may aggregate and interconnect together between the distance-keeping means and the bumps on the LSI chip since the distance-keeping means is disposed straddling over the plurality of terminals that are provided next to each other. This aggregation and interconnection of the conductive particles could short-circuit adjacent terminals, which gives room for improvement.

The present invention has been made in view of these issues and has an object to restrain terminal short-circuiting in a chip-mounting portion.

### Solution to Problem

To achieve the object, a display device in accordance with the present invention includes: a flexible substrate layer; a thin film transistor layer on the flexible substrate layer; and a light-emitting element layer on the thin film transistor layer in such a manner as to correspond to a plurality of subpixels disposed in a display area, the light-emitting element layer including a plurality of light-emitting elements, wherein a frame area is provided surrounding the display area, a terminal section is provided extending in a single direction on an end portion of the frame area, a chip-mounting portion is provided between the display area and the terminal section, the chip-mounting portion being rectangular in a plan view and having a longer side extending in the direction in which the terminal section extends, a plurality of chip-use terminals are provided in a single row on the chip-mounting portion, and a plurality of terminal lines are provided extending parallel to each other in such a manner as to correspond to the plurality of chip-use terminals and being electrically connected respectively to the plurality of chip-use terminals, and a chip support body is provided between the plurality of chip-use terminals on the chip-mounting portion.

### Advantageous Effects of Invention

The present invention can restrain terminal short-circuiting in a chip-mounting portion.

### BRIEF DESCRIPTION OF DRAWINGS

FIG. 1 is a schematic plan view of a structure of an organic EL display device in accordance with a first embodiment of the present invention.

FIG. 2 is a plan view of a display area of an organic EL display panel included in the organic EL display device in accordance with the first embodiment of the present invention.

FIG. 3 is a cross-sectional view of the display area of the organic EL display panel included in the organic EL display device in accordance with the first embodiment of the present invention.

FIG. 4 is an equivalent circuit diagram of a thin film transistor layer included in the organic EL display panel in the organic EL display device in accordance with the first embodiment of the present invention.

FIG. 5 is a cross-sectional view of an organic EL layer included in the organic EL display panel in the organic EL display device in accordance with the first embodiment of the present invention.

FIG. 6 is a plan view of a chip-mounting portion and the surroundings thereof in a frame area of the organic EL display panel in the organic EL display device in accordance with the first embodiment of the present invention.

FIG. 7 is a plan view of output terminals and a chip support body on the chip-mounting portion in the frame area of the organic EL display panel in the organic EL display device in accordance with the first embodiment of the present invention.

FIG. 8 is a plan view of input terminals and a chip support body on the chip-mounting portion in the frame area of the organic EL display panel in the organic EL display device in accordance with the first embodiment of the present invention.

FIG. 9 is a plan view of an end of an integrated circuit chip to be mounted and conductive particles shown in FIG. 7.

FIG. 10 is a cross-sectional view of the organic EL display device taken along line X-X shown in FIG. 9.

FIG. 11 is a cross-sectional view of the organic EL display device taken along line XI-XI shown in FIG. 9.

FIG. 12 is a cross-sectional view of the organic EL display device taken along line XII-XII shown in FIG. 9.

FIG. 13 is a cross-sectional view, equivalent to FIG. 10, of a variation example of the organic EL display device in accordance with the first embodiment of the present invention.

FIG. 14 is a plan view, equivalent to FIG. 7, of output terminals and a chip support body on a chip-mounting portion in a frame area of an organic EL display panel included in an organic EL display device in accordance with a second embodiment of the present invention.

FIG. 15 is a plan view, equivalent to FIG. 14, of a variation example of the organic EL display panel included in the organic EL display device in accordance with the second embodiment of the present invention.

FIG. 16 is a plan view, equivalent to FIG. 7, of output terminals and a chip support body on a chip-mounting portion in a frame area of an organic EL display panel in an organic EL display device in accordance with a third embodiment of the present invention.

FIG. 17 is a plan view, equivalent to FIG. 16, of a first variation example of the organic EL display panel in the organic EL display device in accordance with the third embodiment of the present invention.

FIG. 18 is a plan view, equivalent to FIG. 16, of a second variation example of the organic EL display panel in the organic EL display device in accordance with the third embodiment of the present invention.

FIG. 19 is a plan view, equivalent to FIG. 16, of a third variation example of the organic EL display panel in the organic EL display device in accordance with the third embodiment of the present invention.

FIG. 20 is an enlarged plan view, equivalent to FIG. 6, of a chip-mounting portion in a frame area of an organic EL display panel in an organic EL display device in accordance with a fourth embodiment of the present invention.

### DESCRIPTION OF EMBODIMENTS

The following will describe in detail embodiments of the present invention with reference to drawings. Note that the present invention is not limited by the following embodiments.

### First Embodiment

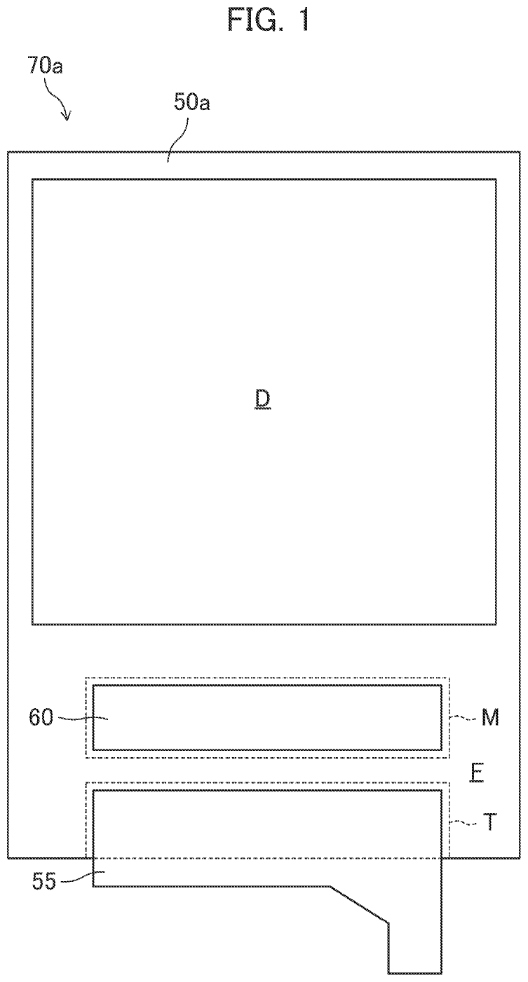

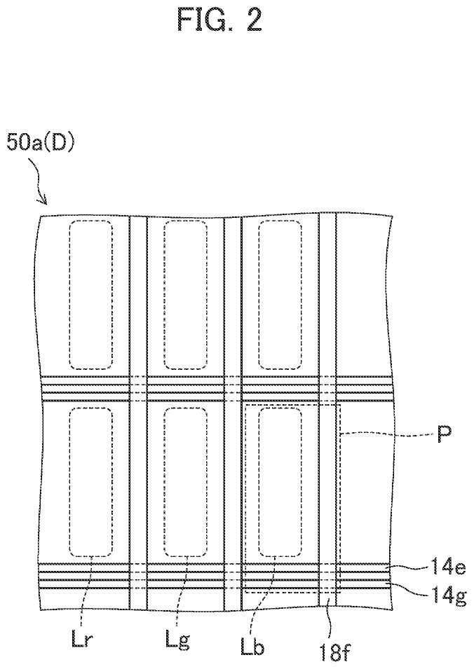

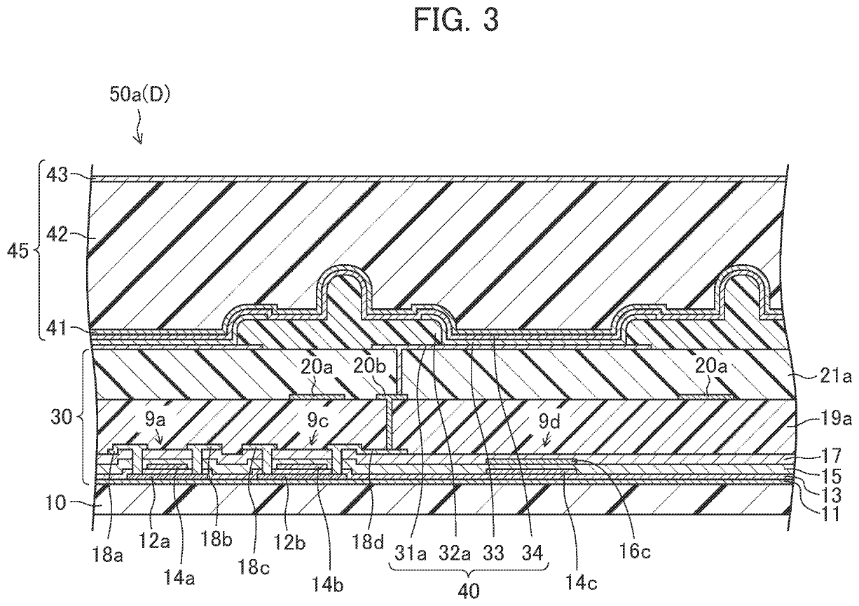

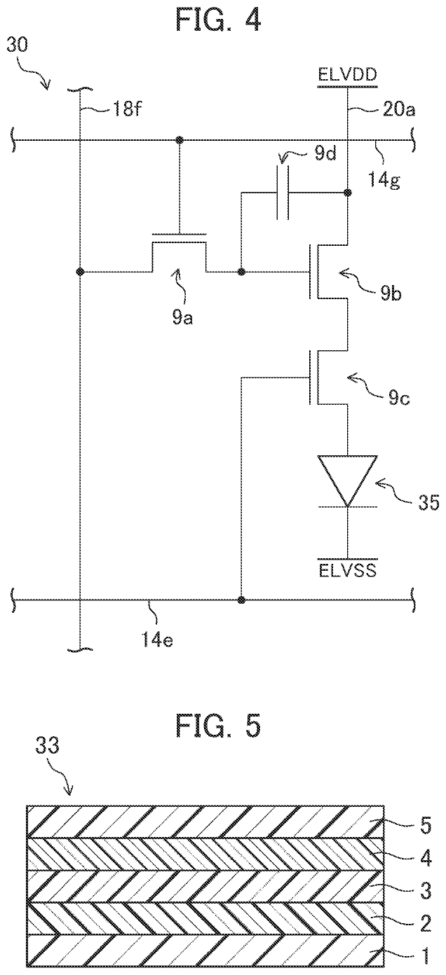

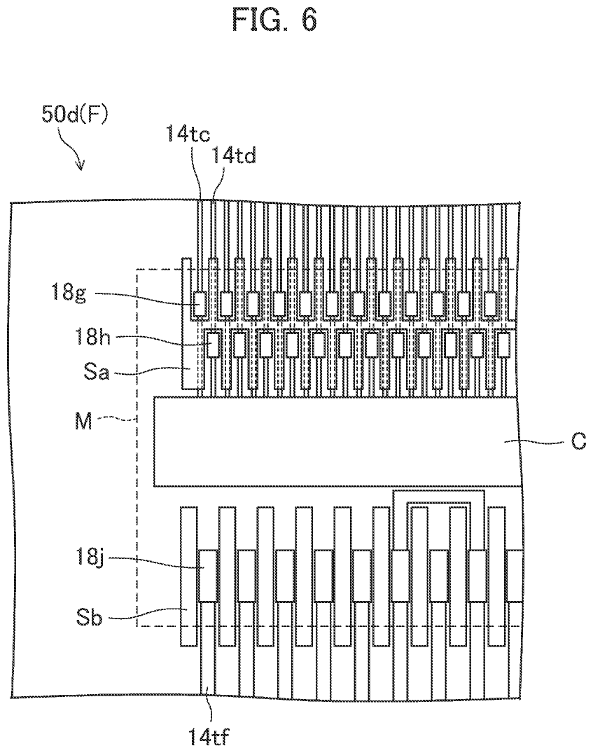

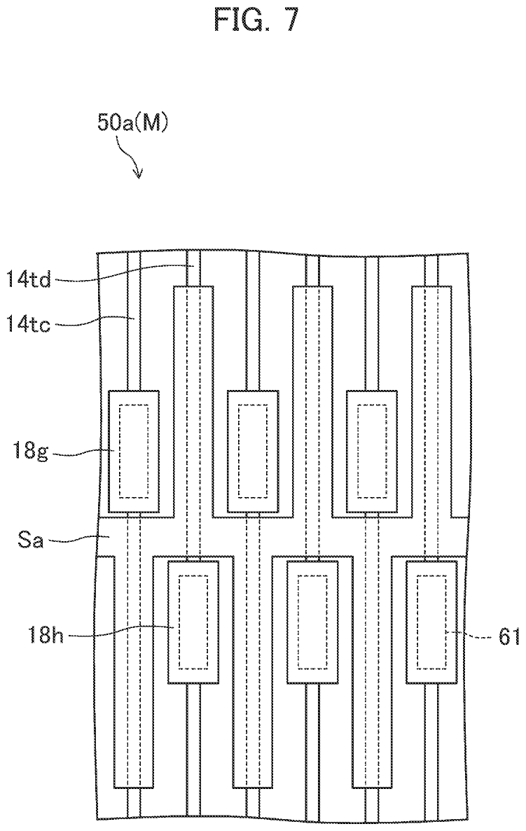

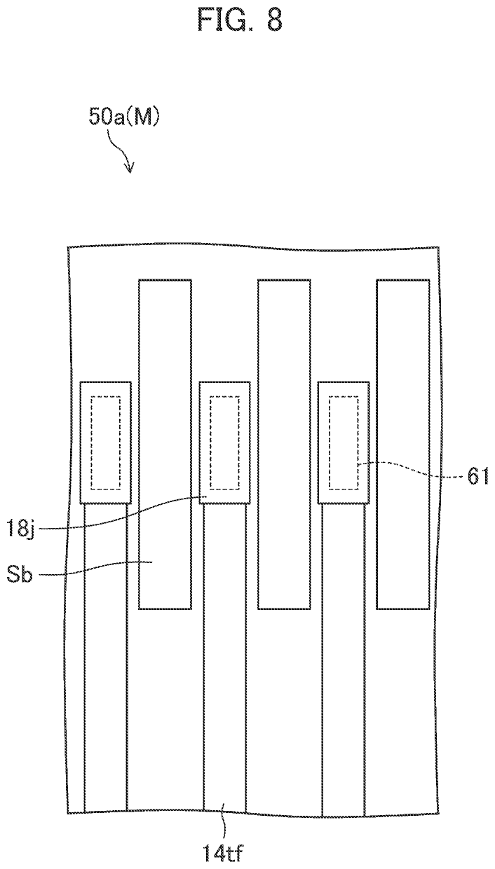

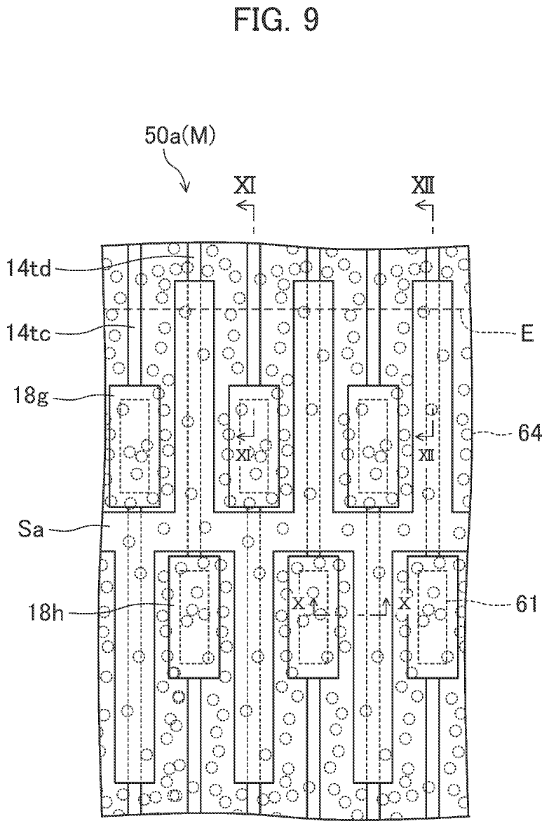

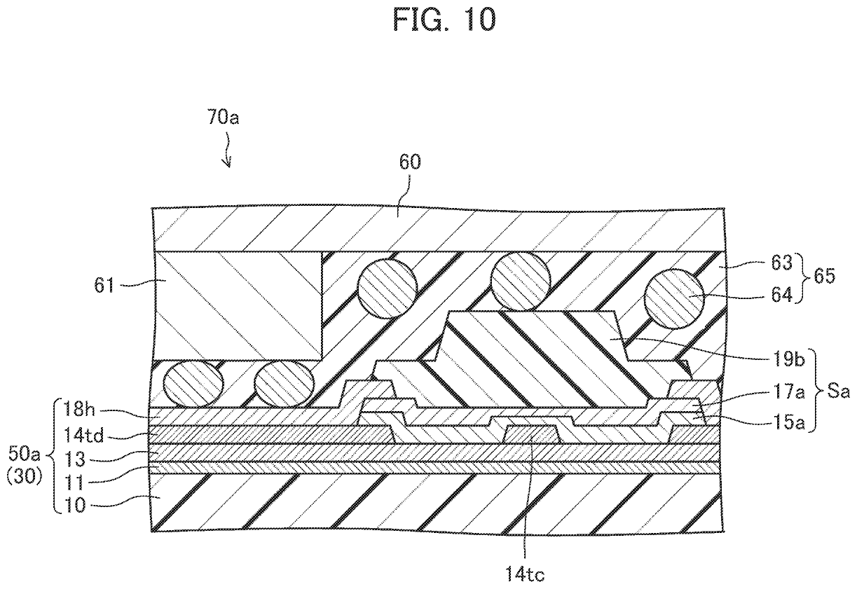

FIGS. 1 to 13 illustrate a first embodiment of the display device in accordance with the present invention. Note that the following embodiments will discuss an organic EL display device including an organic EL element layer as a display device including a light-emitting element layer. Here, FIG. 1 is a schematic plan view of a structure of an organic EL display device 70a in accordance with the present embodiment. In addition, FIG. 2 is a plan view of a display area D of an organic EL display panel 50a included in the organic EL display device 70a. In addition, FIG. 3 is a cross-sectional view of the display area D of the organic EL display panel 50a. In addition, FIG. 4 is an equivalent circuit diagram of a thin film transistor layer 30 included in the organic EL display panel 50a. In addition, FIG. 5 is a cross-sectional view of an organic EL layer 33 included in the organic EL display panel 50a. In addition, FIG. 6 is a plan view of a chip-mounting portion M and the surroundings thereof in a frame area F of the organic EL display panel 50a. In addition, FIG. 7 is a plan view of first output terminals 18g, second output terminals 18h and a chip support body Sa on the chip-mounting portion M in the frame area F of the organic EL display panel 50a. In addition, FIG. 8 is a plan view of input terminals 18j and a chip support bodies Sb on the chip-mounting portion M in the frame area F of the organic EL display panel 50a. In addition, FIG. 9 is a plan view of an end E of an integrated circuit chip 60 to be mounted and conductive particles 64 shown in FIG. 7. In addition, FIGS. 10, 11, and 12 are cross-sectional views of the organic EL display device 70a taken along lines X-X, XI-XI, and XII-XII shown in FIG. 9 respectively. In addition, FIG. 13 is a cross-sectional view, equivalent to FIG. 10, of an organic EL display device 70aa, which is a variation example of the organic EL display device 70a.

Referring to FIG. 1, the organic EL display device 70a includes: the organic EL display panel 50a; the integrated circuit chip 60 mounted to the chip-mounting portion M (detailed later) of the organic EL display panel 50a; and a flexible printed wiring board 55 mounted to a terminal section T (detailed later) of the organic EL display panel 50a.

The organic EL display panel 50a has, for example, the rectangular display area D for displaying images; and the frame area F shaped like a frame surrounding the display area D, as shown in FIG. 1. Note that the present embodiment gives the rectangular display area D as an example. This rectangular shape encompasses, for example, generally rectangular shapes such as those with a curved side(s), those with a round corner(s), and those with a notched side(s).

There is provided a matrix of subpixels P in the display area D as shown in FIG. 2. In addition, in the display area D, for example, a subpixel P including a red-light-emission region Lr for a display in red, a subpixel P including a green-light-emission region Lg for a display in green, and a subpixel P including a blue-light-emission region Lb for a display in blue are provided adjacent to each other as shown in FIG. 2. Note that each pixel in the display area D is formed by, for example, three adjacent subpixels P respectively including the red-light-emission region Lr, the green-light-emission region Lg, and the blue-light-emission region Lb.

As shown in FIG. 1, the frame area F includes, along the bottom thereof, the terminal section T extending in one direction (in the lateral direction in the drawing). In addition, in the frame area F, as shown in FIG. 1, the chip-mounting portion M is provided extending in one direction (in the lateral direction in the drawing) between the display area D and the terminal section T. Note that the chip-mounting portion M is provided in a rectangular shape in a plan view in such a manner that the longer side can extend in a direction in which the terminal section T is extended, as shown in FIG. 1.

Referring to FIG. 3, the organic EL display panel 50a includes: a flexible substrate layer 10; the thin film transistor (hereinafter, may be referred to as TFT) layer 30 provided on the flexible substrate layer 10; an organic EL element layer 40 provided on a TFT layer 30 as a light-emitting element layer; and a sealing film 45 provided so as to cover the organic EL element layer 40.

The flexible substrate layer 10 is made of, for example, a polyimide resin and is flexible. Note that the present embodiment discusses, as an example, the flexible substrate layer 10 made of, for example, a resin such as a polyimide resin. Alternatively, the flexible substrate layer 10 may be made of a metal such as a metal film or a thin metal plate.

The TFT layer 30 includes, as shown in FIG. 3: a base coat film 11 on the flexible substrate layer 10; a plurality of first TFTs 9a, a plurality of second TFTs 9b (see FIG. 4), a plurality of third TFTs 9c, and a plurality of capacitors 9d, all provided on the base coat film 11; and a first planarization film 19a and a second planarization film 21a both provided sequentially on the first TFTs 9a, the second TFTs 9b, the third TFTs 9c, and the capacitors 9d.

In the TFT layer 30, the base coat film 11; a semiconductor pattern layer such as a semiconductor layer 12a (detailed later); a gate insulating film 13; a first wiring layer such as gate lines 14g (detailed later); a first interlayer insulating film 15; a third wiring layer such as an overlying conductive layer 16c (detailed later); a second interlayer insulating film 17; a second wiring layer such as source lines 18f (detailed later); the first planarization film 19a; a fourth wiring layer such as power supply lines 20a; and the second planarization film 21a are provided sequentially on the flexible substrate layer 10, as shown in FIG. 3. Here, the base coat film 11, the gate insulating film 13, the first interlayer insulating film 15, and the second interlayer insulating film 17 are made of, for example, either a monolayer inorganic insulating film of, for example, silicon nitride, silicon oxide, or silicon oxynitride or a stack of any of these inorganic insulating films.

In the TFT layer 30, the plurality of gate lines 14g are provided as the first wiring layer, so as to extend parallel to each other in the lateral direction in the drawing, as shown in FIGS. 2 and 4. In addition, in the TFT layer 30, a plurality of light-emission control lines 14e are provided as the first wiring layer, so as to extend parallel to each other in the lateral direction in the drawing, as shown in FIGS. 2 and 4. Note that the light-emission control lines 14e are provided so as to be adjacent to the respective gate lines 14g as shown in FIG. 2. In addition, in the TFT layer 30, the plurality of source lines 18f are provided as the second wiring layer, so as to extend parallel to each other in the vertical direction in the drawing, as shown in FIGS. 2 and 4. In addition, in the TFT layer 30, the power supply lines 20a are provided as the fourth wiring layer in a lattice form between the first planarization film 19a and the second planarization film 21a as shown in FIG. 3. In addition, in the TFT layer 30, each subpixel P includes one of the first TFTs 9a, one of the second TFTs 9b, one of the third TFTs 9c, and one of the capacitors 9d as shown in FIG. 4.

Referring to FIG. 4, in each subpixel P, the first TFT 9a is electrically connected to an associated one of the gate lines 14g, an associated one of the source lines 18f, and an associated one of the second TFTs 9b. In addition, the first TFT 9a includes the semiconductor layer 12a, the gate insulating film 13, a gate electrode 14a, the first interlayer insulating film 15, the second interlayer insulating film 17, a source electrode 18a, and a drain electrode 18b, all of which are sequentially provided on the base coat film 11, as shown in FIG. 3. Here, the semiconductor layer 12a is provided in an insular manner on the base coat film 11 and has a channel region, a source region, and a drain region as will be detailed later, as shown in FIG. 3. In addition, the gate insulating film 13 is provided so as to cover the semiconductor layer 12a as shown in FIG. 3. In addition, the gate electrode 14a is provided so as to overlap the channel region of the semiconductor layer 12a on the gate insulating film 13 as shown in FIG. 3. In addition, the first interlayer insulating film 15 and the second interlayer insulating film 17 are sequentially provided so as to cover the gate electrode 14a as shown in FIG. 3. In addition, the source electrode 18a and the drain electrode 18b are provided separated from each other on the second interlayer insulating film 17 as shown in FIG. 3. In addition, the source electrode 18a and the drain electrode 18b are electrically connected respectively to the source and drain regions of the semiconductor layer 12a via contact holes formed in the stack of the gate insulating film 13, the first interlayer insulating film 15, and the second interlayer insulating film 17 as shown in FIG. 3.

Referring to FIG. 4, in each subpixel P, the second TFT 9b is electrically connected to an associated one of the first TFT 9a, an associated one of the power supply line 20a, and an associated one of the third TFT 9c. Note that the second TFT 9b has substantially the same structure as the first TFT 9a and the third TFT 9c (detailed later).

In each subpixel P, as shown in FIG. 4, the third TFT 9c is electrically connected to an associated one of the second TFTs 9b, an associated one of first electrodes 31a of organic EL elements 35 (detailed later), and an associated one of the light-emission control lines 14e. In addition, referring to FIG. 3, the third TFT 9c includes a semiconductor layer 12b, the gate insulating film 13, a gate electrode 14b, the first interlayer insulating film 15, the second interlayer insulating film 17, a source electrode 18c, and a drain electrode 18d, all of which are sequentially provided on the base coat film 11. Here, the semiconductor layer 12b is provided in an insular manner on the base coat film 11 and has a channel region, a source region, and a drain region similarly to the semiconductor layer 12a as shown in FIG. 3. In addition, the gate insulating film 13 is provided so as to cover the semiconductor layer 12b as shown in FIG. 3. In addition, the gate electrode 14b is provided so as to overlap the channel region of the semiconductor layer 12b on the gate insulating film 13 as shown in FIG. 3. In addition, the first interlayer insulating film 15 and the second interlayer insulating film 17 are sequentially provided so as to cover the gate electrode 14b as shown in FIG. 3. In addition, the source electrode 18c and the drain electrode 18d are provided separated from each other on the second interlayer insulating film 17 as shown in FIG. 3. In addition, the source electrode 18c and the drain electrode 18d are electrically connected respectively to the source and drain regions of the semiconductor layer 12b via contact holes formed in the stack of the gate insulating film 13, the first interlayer insulating film 15, and the second interlayer insulating film 17 as shown in FIG. 3.

Note that the present embodiment discusses an example where the first TFTs 9a, the second TFTs 9b, and the third TFTs 9c have a top gate structure. Alternatively, the first TFTs 9a, the second TFTs 9b, and the third TFTs 9c may have a bottom gate structure.

Referring to FIG. 4, in each subpixel P, the capacitor 9d is electrically connected to an associated one of the first TFTs 9a and an associated one of the power supply lines 20a. Here, as shown in FIG. 3, the capacitor 9d includes: an underlying conductive layer 14c provided as the first wiring layer; the first interlayer insulating film 15 provided so as to cover the underlying conductive layer 14c; and the overlying conductive layer 16c provided as the third wiring layer so as to overlap the underlying conductive layer 14c on the first interlayer insulating film 15. Note that the overlying conductive layer 16c is electrically connected to the power supply line 20a via contact holes (not shown) formed in the second interlayer insulating film 17 and the first planarization film 19a.

The first planarization film 19a and the second planarization film 21a have a flat surface in the display area D and is made of, for example, either an organic resin material such as a polyimide resin or an acrylic resin or a polysiloxane-based SOG (spin on glass) material. Here, between the first planarization film 19a and the second planarization film 21a, apart from the power supply line 20a described above, there is provided a relay electrode 20b as the fourth wiring layer as shown in FIG. 3.

The organic EL element layer 40 includes the plurality of first electrodes 31a, a common edge cover 32a, the plurality of organic EL layers 33, and a common, second electrode 34, all of which are sequentially provided correspondingly to the plurality of subpixels P. Here, in each subpixel P, the organic EL element 35 (see FIG. 4) includes an associated one of the first electrodes 31a, an associated one of the organic EL layers 33, and the second electrode 34. In the organic EL element layer 40, the plurality of organic EL element 35 are disposed so as to form a matrix.

The plurality of first electrodes 31a are provided correspondingly to the plurality of subpixels P, so as to form a matrix on the second planarization film 21a, as shown in FIG. 3. Here, referring to FIG. 3, the first electrode 31a is electrically connected to the drain electrode 18d of the third TFT 9c via a contact hole formed in the first planarization film 19a, the relay electrode 20b, and a contact hole formed in the second planarization film 21a. In addition, the first electrode 31a has a function of injecting holes to the organic EL layer 33. In addition, the first electrode 31a is more preferably made of a material that has a large work function to improve the efficiency of hole injection to the organic EL layer 33. Here, the material for the first electrode 31a is, as an example, a metal such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), or tin (Sn). In addition, the material for the first electrode 31a may be an alloy such as astatine-astatine oxide (At—AtO₂). Furthermore, the material for the first electrode 31a may be an electrically conductive oxide such as tin oxide (SnO), zinc oxide (ZnO), indium tin oxide (ITO), or indium zinc oxide (IZO). In addition, the first electrode 31a may be made of a stack of layers each made of any of these materials. Note that examples of compound materials that have a large work function include indium tin oxide (ITO) and indium zinc oxide (IZO).

The edge cover 32a is provided in a lattice form so as to cover a peripheral end portion of each first electrode 31a as shown in FIG. 3. Here, the edge cover 32a is made of, for example, either an organic resin material such as a polyimide resin or an acrylic resin or a polysiloxane-based SOG material.

The plurality of organic EL layers 33 are provided correspondingly to the plurality of subpixels P, so as to form a matrix on the first electrodes 31a as shown in FIG. 3. Here, referring to FIG. 5, each organic EL layer 33 includes a hole injection layer 1, a hole transport layer 2, a light-emitting layer 3, an electron transport layer 4, and an electron injection layer 5, all of which are sequentially provided on the first electrode 31a.

The hole injection layer 1 is alternatively referred to as the anode buffer layer and has a function of bringing the energy levels of the first electrode 31a and the organic EL layer 33 closer to each other to improve the efficiency of hole injection from the first electrode 31a to the organic EL layer 33. Here, the hole injection layer 1 is made of, for example, a triazole derivative, an oxadiazole derivative, an imidazole derivative, a polyaryl alkane derivative, a pyrazoline derivative, a phenylenediamine derivative, an oxazole derivative, a styryl anthracene derivative, a fluorenone derivative, a hydrazone derivative, or a stilbene derivative.

The hole transport layer 2 has a function of improving the efficiency of hole transport from the first electrode 31a to the organic EL layer 33. Here, the hole transport layer 2 is made of, for example, a porphyrin derivative, an aromatic tertiary amine compound, a styryl amine derivative, polyvinyl carbazole, poly-p-phenylene vinylene, polysilane, a triazole derivative, an oxadiazole derivative, an imidazole derivative, a polyaryl alkane derivative, a pyrazoline derivative, a pyrazolone derivative, a phenylenediamine derivative, an aryl amine derivative, an amine-substituted chalcone derivative, an oxazole derivative, a styryl anthracene derivative, a fluorenone derivative, a hydrazone derivative, a stilbene derivative, hydrogenated amorphous silicon, hydrogenated amorphous silicon carbide, zinc sulfide, or zinc selenide.

The light-emitting layer 3 is injected with holes and electrons respectively from the first electrode 31a and the second electrode 34 when the first electrode 31a and the second electrode 34 are placed under applied voltage. The injected holes and electrons recombine in the light-emitting layer 3. Here, the light-emitting layer 3 is made of a material that has a high luminous efficiency. The light-emitting layer 3 is made of, for example, a metal oxinoid compound [8-hydroxy quinoline metal complex], a naphthalene derivative, an anthracene derivative, a diphenyl ethylene derivative, a vinyl acetone derivative, a triphenyl amine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styryl amine derivative, a bis(styryl)benzene derivative, a tris(styryl)benzene derivative, a perylene derivative, a perynone derivative, an amino pyrene derivative, a pyridine derivative, a rhodamine derivative, an acridine derivative, phenoxazone, a quinacridone derivative, rubrene, poly-p-phenylene vinylene, or polysilane.

The electron transport layer 4 has a function of efficiently transporting electrons to the light-emitting layer 3. Here, the electron transport layer 4 is made of, for example, an organic compound such as an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, or a metal oxinoid compound.

The electron injection layer 5 has a function of bringing the energy levels of the second electrode 34 and the organic EL layer 33 closer to each other to improve the efficiency of electron injection from the second electrode 34 to the organic EL layer 33. This function enables lowering the drive voltage of the organic EL element. Note that the electron injection layer 5 is alternatively referred to as the cathode buffer layer. Here, the electron injection layer 5 is made of, for example, an inorganic alkali compound such as lithium fluoride (LiF), magnesium fluoride (MgF₂), calcium fluoride (CaF₂), strontium fluoride (SrF₂), or barium fluoride (BaF₂), aluminum oxide (Al₂O₃), or strontium oxide (SrO).

The second electrode 34 is provided on the plurality of organic EL layers 33, so as to be common to the plurality of subpixels P, that is, so as to cover the organic EL layers 33 and the edge cover 32a as shown in FIG. 3. In addition, the second electrode 34 has a function of injecting electrons to the organic EL layers 33. In addition, the second electrode 34 is more preferably made of a material that has a small work function to improve the efficiency of electron injection of the organic EL layers 33. Here, the second electrode 34 is made of, for example, silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), or lithium fluoride (LiF). In addition, the second electrode 34 may be made of, for example, an alloy such as a magnesium-copper (Mg—Cu), magnesium-silver (Mg—Ag), sodium-potassium (Na—K), astatine-astatine oxide (At—AtO₂), lithium-aluminum (Li—Al), lithium-calcium-aluminum (Li—Ca—Al), or lithium fluoride-calcium-aluminum (LiF—Ca—Al). In addition, the second electrode 34 may be made of, for example, an electrically conductive oxide such as tin oxide (SnO), zinc oxide (ZnO), indium tin oxide (ITO), or indium zinc oxide (IZO). In addition, the second electrode 34 may include a stack of layers each made of any of these materials. Note that examples of materials that have a small work function include magnesium (Mg), lithium (Li), lithium fluoride (LiF), magnesium-copper (Mg—Cu), magnesium-silver (Mg—Ag), sodium-potassium (Na—K), lithium-aluminum (Li—Al), lithium-calcium-aluminum (Li—Ca—Al), or lithium fluoride-calcium-aluminum (LiF—Ca—Al).

Referring to FIG. 3, the sealing film 40 includes a first inorganic sealing film 41, an organic sealing film 42, and a second inorganic sealing film 43, all of which are provided so as to cover the second electrode 34 and sequentially stacked over the second electrode 34, to have a function of protecting the organic EL layer 33 in the organic EL element 35 from, for example, water and oxygen. Here, the first inorganic sealing film 41 and the second inorganic sealing film 43 include, for example, an inorganic insulating film such as a silicon nitride film, a silicon oxide film, or a silicon oxynitride film. In addition, the organic sealing film 42 is made of, for example, an organic resin material such as an acrylic resin, an epoxy resin, a silicone resin, a polyurea resin, a parylene resin, a polyimide resin, or a polyamide resin. Note that in the frame area F of the organic EL display panel 50a, there is provided a frame-shaped, first damming wall surrounding the display area D and a frame-shaped, second damming wall surrounding the first damming wall, both for the purpose of restraining ink that will form the organic sealing film 42 from spreading.

In addition, as shown in FIG. 6, the organic EL display panel 50a includes: rectangularly shaped under-chip circuitry C provided so as to extend in the lateral direction in the drawing in the chip-mounting portion M of the frame area F; a plurality of first output-end terminal lines 14tc and a plurality of second output-end terminal lines 14td provided so as to extend parallel to each other on the display area D side (toward the top of the drawing) of the under-chip circuitry C; and a plurality of input-end terminal lines 14tf provided so as to extend parallel to each other on the terminal section T side (toward the bottom of the drawing) of the under-chip circuitry C. Here, the plurality of first output-end terminal lines 14tc and the plurality of second output-end terminal lines 14td are alternately provided in the direction in which the chip-mounting portion M is extended (in the lateral direction in the drawing) as shown in FIGS. 6 and 7. Note that the first output-end terminal lines 14tc, the second output-end terminal lines 14td, and the input-end terminal lines 14tf are provided as the first wiring layer.

In addition, referring to FIG. 6, the organic EL display panel 50a includes, in the chip-mounting portion M of the frame area F: the plurality of first output terminals 18g provided as chip-use terminals on the display area D side (toward the top of the drawing) of the under-chip circuitry C so as to be aligned in a single row in the display area D side along the longer side of the display area D side of the under-chip circuitry C; the plurality of second output terminals 18h provided as chip-use terminals on the terminal section T side (toward the bottom of the drawing) of the under-chip circuitry C so as to be aligned in a single row in the display area D side along the longer side of the display area D side of the under-chip circuitry C; and the plurality of input terminals 18j provided as chip-use terminals on the terminal section T side (toward the bottom of the drawing) of the under-chip circuitry C so as to be aligned in a single row along the longer side of the terminal section T side of the under-chip circuitry C. Here, referring to FIGS. 6 and 7, the plurality of first output terminals 18g and the plurality of second output terminals 18h are alternately provided in a staggered pattern in the direction in which the chip-mounting portion M is extended (in the lateral direction in the drawing). Note that the first output terminals 18g, the second output terminals 18h, and the input terminals 18j are provided as the second wiring layer. In addition, the plurality of first output terminals 18g are stacked respectively on the plurality of first output-end terminal lines 14tc and electrically connected respectively to the plurality of first output-end terminal lines 14tc. In addition, referring to FIG. 10, the plurality of second output terminals 18h are stacked respectively on the plurality of second output-end terminal lines 14td and electrically connected respectively to the plurality of second output-end terminal lines 14td. In addition, the plurality of input terminals 18j are stacked respectively on the plurality of input-end terminal lines 14tf and electrically connected respectively to the plurality of input-end terminal lines 14tf.

In addition, referring to FIGS. 6, 7, and 8, the organic EL display panel 50a includes, in the chip-mounting portion M of the frame area F: the chip support body Sa provided like double-sided comb teeth, but in a single piece, between the plurality of first output terminals 18g and between the plurality of second output terminals 18h; and the chip support bodies Sb in an insular manner, one each in every gap between the plurality of input terminals 18j.

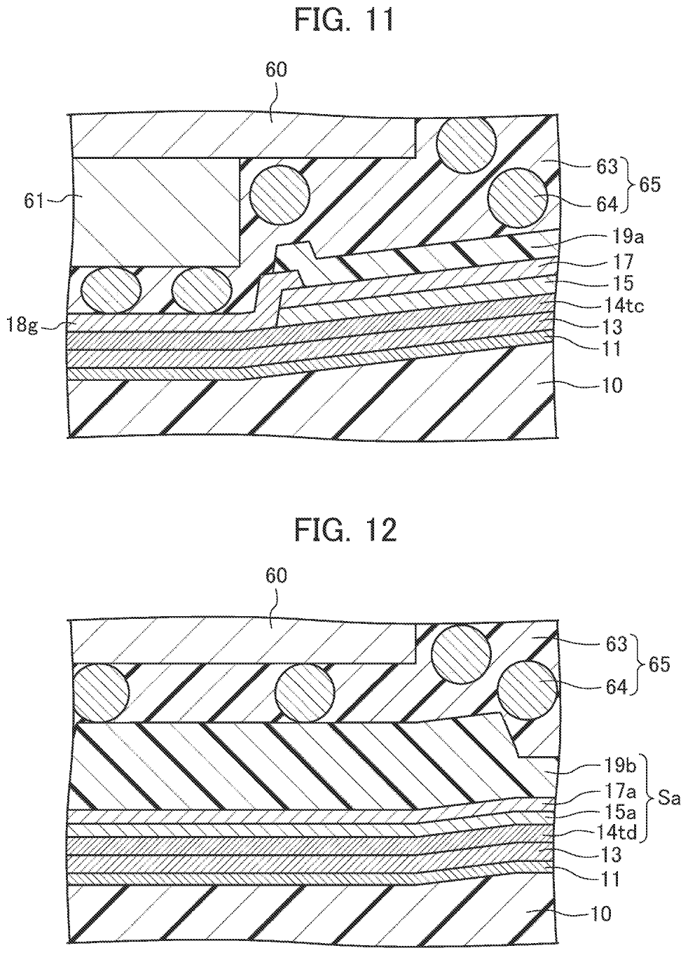

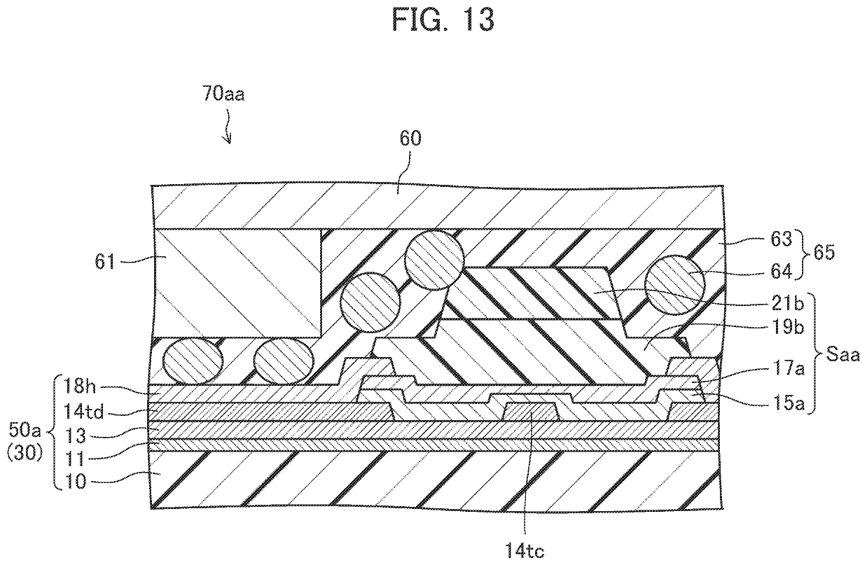

The chip support body Sa, as shown in FIG. 10, includes: a first inorganic insulating layer 15a made of the same material, and provided in the same layer, as the first interlayer insulating film 15; a second inorganic insulating layer 17a provided on the first inorganic insulating layer 15a and made of the same material, and provided in the same layer, as the second interlayer insulating film 17; and an organic insulating layer 19b provided on the second inorganic insulating layer 17a and made of the same material, and provided in the same layer, as the first planarization film 19a. Here, the organic insulating layer 19b, as shown in FIG. 10, is thicker in the central portion thereof in terms of the width direction thereof than in both end portions thereof in terms of the width direction thereof. Note that as shown in FIG. 10, since the second output-end terminal lines 14td and the second output terminals 18h (and the first output-end terminal lines 14tc and the first output terminals 18g) are extended to both end portions of the chip support body Sa in terms of the width direction thereof, the integrated circuit chip 60 and the chip support body Sa are separated only by a small gap. This restrains warping of the panel at the first output terminals 18g and the second output terminals 18h in pressure bonding of the chip, which in turn enables restraining breakage of the first output terminals 18g, the second output terminals 18h, the first output-end terminal lines 14tc, and the second output-end terminal lines 14td (see FIG. 11). In addition, as shown in FIG. 6, since the display area D side of the chip support body Sa is disposed outside the chip-mounting portion M (outside a peripheral end E of the integrated circuit chip 60), the integrated circuit chip 60 and the chip support body Sa are separated only by a small gap at sites where there are provided no bumps 61, which enables restraining warping of the panel in pressure bonding of the chip (see FIG. 12).

Similarly to the chip support body Sa, each chip support body Sb includes: a first inorganic insulating layer 15a made of the same material, and provided in the same layer, as the first interlayer insulating film 15; a second inorganic insulating layer 17a provided on the first inorganic insulating layer 15a and made of the same material, and provided in the same layer, as the second interlayer insulating film 17; and an organic insulating layer 19b provided on the second inorganic insulating layer 17a and made of the same material, and provided in the same layer, as the first planarization film 19a. Note that since the input-end terminal lines 14tf and the input terminals 18j are extended to both end portions of the chip support body Sb in terms of the width direction thereof, the integrated circuit chip 60 and the chip support bodies Sb are separated only by a small gap. Warping of the panel at the input terminals 18j in pressure bonding of the chip is restrained, which enables restraining of the breakage of the input terminals 18j and the input-end terminal lines 14tf. In addition, as shown in FIG. 6, since the terminal section T side of the chip support body Sb is disposed outside the chip-mounting portion M, the integrated circuit chip 60 and the chip support body Sb are separated only by a small gap at sites where there are provided no bumps 61, which enables restraining warping of the panel in pressure bonding of the chip.

Note that the present embodiment has discussed an example where the organic EL display device 70a includes the chip support bodies Sa and Sb that in turn include a single-layered organic insulating layer. Alternatively, the chip support bodies Sa and Sb may be the organic EL display device 70aa that includes a chip support body Saa that in turn includes a double-layered organic insulating layer shown in FIG. 13. Here, in the organic EL display device 70aa, as shown in FIG. 13, the chip support body Saa includes: a first inorganic insulating layer 15a made of the same material, and provided in the same layer, as the first interlayer insulating film 15; a second inorganic insulating layer 17a provided on the first inorganic insulating layer 15a and made of the same material, and provided in the same layer, as the second interlayer insulating film 17; the first organic insulating layer 19b provided on the second inorganic insulating layer 17a and made of the same material, and provided in the same layer, as the first planarization film 19a; and a second organic insulating layer 21b provided on the first organic insulating layer 19b and made of the same material, and provided in the same layer, as the second planarization film 21a. Note that as shown in FIG. 13, the first organic insulating layer 19b is thicker in the central portion thereof in terms of the width direction thereof than in both end portions thereof in terms of the width direction thereof. In addition, as shown in FIG. 13, the second organic insulating layer 21b has a smaller width than does the first organic insulating layer 19b.

The plurality of bumps 61 are provided on the back face of the integrated circuit chip 60, as shown in FIG. 10. Here, the plurality of first output terminals 18g, the plurality of second output terminals 18h, and the plurality of input terminals 18j, all of which are provided in the chip-mounting portion M of the frame area F of the organic EL display panel 50a, have a plurality of chip-use terminals that correspond to the plurality of bumps 61 as shown in FIGS. 7 and 8. In addition, the plurality of chip-use terminals (the first output terminals 18g, the second output terminals 18h, and the input terminals 18j) are electrically connected respectively to the plurality of bumps 61 via the anisotropic conductive film 65, specifically, via the conductive particles 64 in an anisotropic conductive film 65, as shown in FIGS. 9 and 10. Here, the anisotropic conductive film 65 includes, for example: a resin material 63 made of a thermosetting resin; and the conductive particles 64 dispersed in the resin material 63, as shown in FIG. 10.

The flexible printed wiring board (FPC: flexible printed circuits) 55 is mounted to the terminal section T via the anisotropic conductive film 65.

In the aforementioned organic EL display device 70a, in each subpixel P, the first TFT 9a is turned on by a gate signal fed to the first TFT 9a via the gate line 14g, and a prescribed voltage corresponding to the source signal is written to the gate electrode of the second TFT 9b and to the capacitor 9d via the source line 18f. The third TFT 9c is turned on when a light-emission control signal is fed to the third TFT 9c via the light-emission control line 14e, and the light-emitting layer 3 in the organic EL layer 33 emits light by an electric current in accordance with the gate voltage of the second TFT 9b fed from the power supply line 20a to the organic EL layer 33, which produces an image display. Note that in the organic EL display device 70a, even when the first TFT 9a is turned off, the gate voltage of the second TFT 9b is retained by the capacitor 9d. Therefore, the light-emitting layer 3 continuously emits light in the subpixel P until a gate signal is fed in the next frame.

A description is given next of a method of manufacturing the organic EL display device 70a in accordance with the present embodiment. Note that the method of manufacturing the organic EL display device in accordance with the present embodiment includes an organic EL display panel fabrication step including a TFT layer formation step, an organic EL element layer formation step, and a sealing film formation step; and a mounting step.

### Organic EL Display Panel Fabrication Step

### TFT Layer Formation Step

First, for example, after coating a glass substrate with a non-photosensitive polyimide resin (having a thickness of approximately 10 m), this coating film is subjected to pre-baking and post-baking to form the flexible substrate layer 10.

Subsequently, a silicon oxide film (having a thickness of approximately 500 nm) and a silicon nitride film (having a thickness of approximately 100 nm) are sequentially formed by, for example, plasma CVD on the front face of the substrate on which the flexible substrate layer 10 has been formed, to form the base coat film 11.

Subsequently, for example, an amorphous silicon film (having a thickness of approximately 50 nm) is formed by plasma CVD on the front face of the substrate on which the base coat film 11 has been formed. After the amorphous silicon film is crystallized by, for example, laser annealing to form a semiconductor film that is a polysilicon film, the semiconductor film is patterned to form a semiconductor pattern layer including, for example, the semiconductor layer 12a.

Thereafter, an inorganic insulating film (approximately 100 nm) such as a silicon oxide film is formed by, for example, plasma CVD on the front face of the substrate on which the semiconductor pattern layer has been formed, to form the gate insulating film 13 so as to cover, for example, the semiconductor layer 12a.

Furthermore, after a molybdenum film (having a thickness of approximately 250 nm) is formed by, for example, sputtering on the front face of the substrate on which the gate insulating film 13 has been formed, the molybdenum film is patterned to form the first wiring layer including, for example, the gate lines 14g, the first output-end terminal lines 14tc, the second output-end terminal lines 14td, and the input-end terminal lines 14tf.

Subsequently, by doping with impurity ions using the aforementioned first wiring layer as a mask, intrinsic regions and conductive regions are formed in, for example, the semiconductor layer 12a.

Thereafter, a silicon nitride film (having a thickness of approximately 100 nm) is formed by, for example, plasma CVD on the front face of the substrate on which, for example, the semiconductor layer 12a having intrinsic regions and conductive regions has been formed, to form the first interlayer insulating film 15.

Subsequently, after a molybdenum film (having a thickness of approximately 250 nm) is formed by, for example, sputtering on the front face of the substrate on which the first interlayer insulating film 15 has been formed, the molybdenum film is patterned to form the third wiring layer including, for example, the overlying conductive layer 16c.

Furthermore, a silicon oxide film (having a thickness of approximately 300 nm) and a silicon nitride film (having a thickness of approximately 200 nm) are sequentially formed by, for example, plasma CVD on the front face of the substrate on which the aforementioned third wiring layer has been formed, to form the second interlayer insulating film 17.

Thereafter, the gate insulating film 13, the first interlayer insulating film 15, and the second interlayer insulating film 17 are patterned in a suitable manner to form contact holes and also form the first inorganic insulating layer 15a and the second inorganic insulating layer 17a.

Furthermore, after a titanium film (having a thickness of approximately 50 nm), an aluminum film (having a thickness of approximately 600 nm), and a titanium film (having a thickness of approximately 50 nm) are sequentially formed by, for example, sputtering on the front face of the substrate in which the aforementioned contact holes have been formed, these metal stack-layer films are patterned to form the second wiring layer including, for example, the source lines 18f, the first output terminals 18g, the second output terminals 18h, and the input terminals 18j.

Furthermore, after the front face of the substrate on which the aforementioned second wiring layer has been formed is coated with a photosensitive polyimide resin (having a thickness of approximately 2.5 m) by, for example, spin-coating or slit-coating, the coating film is subjected to pre-baking, exposure to light, development, and post-baking, to form, for example, the first planarization film 19a and the organic insulating layer 19b. Note that the organic insulating layer 19b is made thicker in the central portion thereof in terms of the width direction thereof than in both end portions thereof in terms of the width direction thereof by, for example, half exposure to light using a gray tone mask.

Thereafter, after a titanium film (having a thickness of approximately 50 nm), an aluminum film (having a thickness of approximately 600 nm), and a titanium film (having a thickness of approximately 50 nm) are sequentially formed by, for example, sputtering on the front face of the substrate on which, for example, the first planarization film 19a has been formed, this metal stack-layer film is patterned to form the fourth wiring layer including, for example, the power supply lines 20a.

Finally, after the front face of the substrate on which the aforementioned fourth wiring layer has been formed is coated with a polyimide-based photosensitive resin film (having a thickness of approximately 2.5 μm) by, for example, spin-coating or slit-coating, this coating film is subjected to pre-baking, exposure to light, development, and post-baking to form, for example, the second planarization film 21a.

The TFT layer 30 can be formed as described in the foregoing.

### Organic EL Element Layer Formation Step

The first electrodes 31a, the edge cover 32a, the organic EL layers 33 (the hole injection layer 1, the hole transport layer 2, the light-emitting layer 3, the electron transport layer 4, and the electron injection layer 5), and the second electrode 34 are formed on the second planarization film 21a in the TFT layer 30 formed by a well-known method in the aforementioned TFT layer formation step, to form the organic EL element layer 40.

### Sealing Film Formation Step

First, for example, an inorganic insulating film such as a silicon nitride film, a silicon oxide film, or a silicon oxynitride film is formed by plasma CVD using a mask on the front face of the substrate on which the organic EL element layer 40 has been formed in the aforementioned organic EL element layer formation step, to form the first inorganic sealing film 41.

Subsequently, an organic resin material such as an acrylic resin is formed by, for example, inkjet printing on the front face of the substrate on which the first inorganic sealing film 41 has been formed, to form the organic sealing film 42.

Thereafter, the second inorganic sealing film 43 is formed by forming, for example, an inorganic insulating film such as a silicon nitride film, a silicon oxide film, or a silicon oxynitride film by plasma CVD using a mask on the front face of the substrate on which the organic sealing film 42 has been formed, to form the sealing film 45.

Furthermore, after attaching a front-side protection sheet (not shown) onto the front face of the substrate on which the sealing film 45 has been formed, a laser beam is projected from the glass substrate side of the flexible substrate layer 10 to lift off the glass substrate from the bottom face of the flexible substrate layer 10. Subsequently, a back-side protection sheet (not shown) is attached to the bottom face of the flexible substrate layer 10 from which the glass substrate has been lifted off.

The organic EL display panel 50a can be formed as described in the foregoing.

### Mounting Step

First, the protection sheet is partially removed by, for example, projecting a laser beam onto the front-side protection sheet of the organic EL display panel 50a formed in the aforementioned organic EL display panel fabrication step, to expose the chip-mounting portion M and the terminal section T.

Subsequently, the anisotropic conductive film 65 is temporarily fixed to the chip-mounting portion M and the terminal section T.

Furthermore, after aligning the integrated circuit chip 60 and the flexible printed wiring board 55 respectively to the chip-mounting portion M and the terminal section T, the integrated circuit chip 60 and the flexible printed wiring board 55 are respectively pressed using a pressure bonding tool, to mount the integrated circuit chip 60 and the flexible printed wiring board 55 respectively to the chip-mounting portion M and the terminal section T.

The organic EL display device 70a in accordance with the present embodiment can be manufactured as described in the foregoing.

As described above, in the organic EL display device 70a in accordance with the present embodiment, in the chip-mounting portion M of the frame area F, the chip support body Sa is provided like double-sided comb teeth between the plurality of first output terminals 18g and between the plurality of second output terminals 18h, and the chip support bodies Sb are provided in an insular manner, one each in every gap between the plurality of input terminals 18j. Therefore, the conductive particles 64 in the anisotropic conductive film 65 are transported by being extruded by the chip support body Sa and the chip support bodies Sb in the mounting step, so that the conductive particles 64 are relatively dense on the chip-use terminals of the first output terminals 18g, the second output terminals 18h, and the input terminals 18j and relatively sparse between the chip-use terminals. This renders the conductive particles 64 less likely to interconnect between the adjacent chip-use terminals, enabling restraining short-circuiting between the adjacent chip-use terminals due to interconnection of the conductive particles 64, which in turn enables restraining short-circuiting between the terminals on the chip-mounting portion M.

In addition, in the organic EL display device 70a in accordance with the present embodiment, since the chip support bodies Sa and Sb are provided near the chip-use terminals of the plurality of first output terminals 18g, the plurality of second output terminals 18h, and the plurality of input terminals 18j in the chip-mounting portion M of the frame area F, the organic EL display panel 50a can be restrained from warping near the bumps 61 of the integrated circuit chip 60 in the mounting step. Hence, cracks are restrained from developing in the base coat film 11, the gate insulating film 13, the first interlayer insulating film 15, and the second interlayer insulating film 17 in the organic EL display panel 50a, and the first output-end terminal lines 14tc, the second output-end terminal lines 14td, and the input-end terminal lines 14tf, which are provided between the gate insulating film 13 and the first interlayer insulating film 15, can be restrained from breaking.

### Second Embodiment

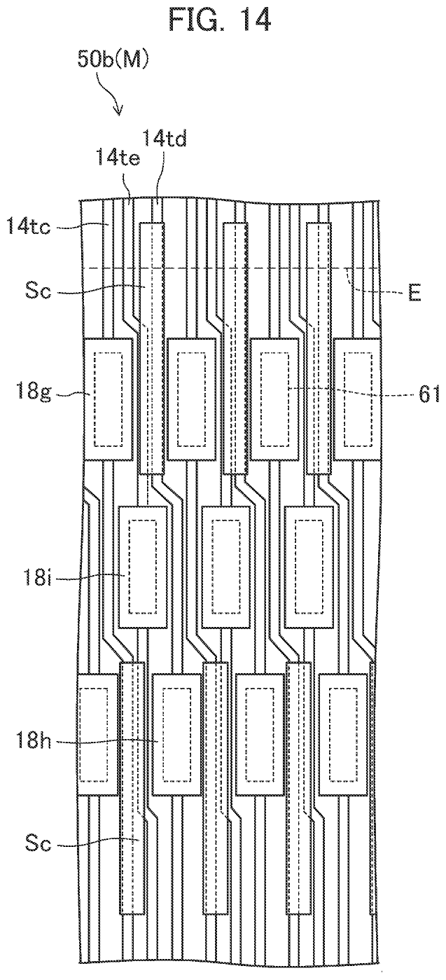

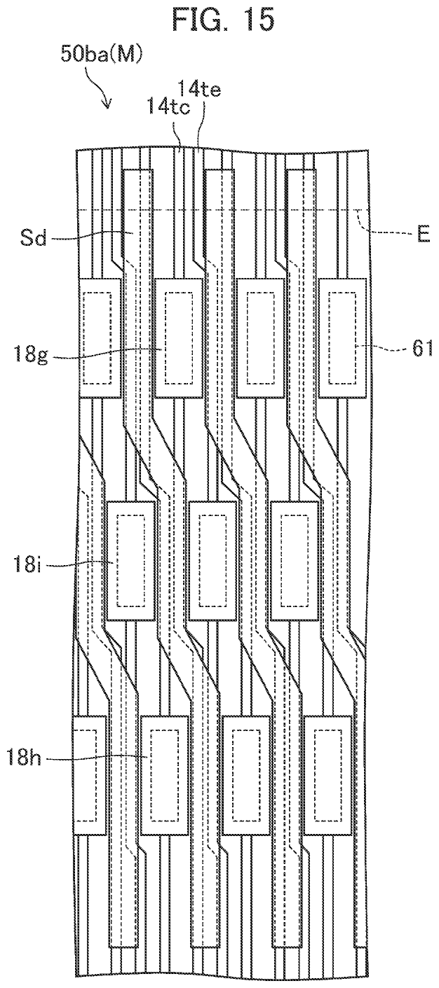

FIGS. 14 and 15 illustrate a second embodiment of the display device in accordance with the present invention. Here, FIG. 14 is a plan view, equivalent to FIG. 7, of the first output terminals 18g, the second output terminals 18h, third output terminals 18i, and a chip support body Sc in the chip-mounting portion M of the frame area F of an organic EL display panel 50b that is a part of an organic EL display device in accordance with the present embodiment. In addition, FIG. 15 is a plan view, equivalent to FIG. 14, of an organic EL display panel 50ba, which is a variation example of the organic EL display panel 50b. Note that members of this and subsequent embodiments that are the same as those shown in FIGS. 1 to 13 are indicated by the same reference signs or numerals, and detailed description thereof is omitted.

The first embodiment above discussed, as an example, the organic EL display device 70a including the organic EL display panel 50a provided with the output terminals 18g and 18h having a 2-step structure in a plan view. The present embodiment discusses, as an example, an organic EL display device including the organic EL display panel 50b provided with output terminals 18g, 18h, and 18i having a 3-step structure in a plan view.

Similarly to the organic EL display device 70a in accordance with the first embodiment above, the organic EL display device in accordance with the present embodiment includes: an organic EL display panel 50b; an integrated circuit chip 60 mounted to the chip-mounting portion M of the organic EL display panel 50b; and a flexible printed wiring board 55 mounted to the terminal section T of the organic EL display panel 50b.

Similarly to the organic EL display panel 50a in accordance with the first embodiment above, the organic EL display panel 50b has, for example: a rectangular display area D for displaying images; and a frame area F shaped like a frame surroundings the display area D.

In addition, similarly to the organic EL display panel 50a in accordance with the first embodiment above, the organic EL display panel 50b includes: a flexible substrate layer 10; a TFT layer 30 on the flexible substrate layer 10; an organic EL element layer 40 on the TFT layer 30; and a sealing film 45 provided so as to cover the organic EL element layer 40.

In addition, the organic EL display panel 50b includes, in the chip-mounting portion M of the frame area F: under-chip circuitry C; a plurality of first output-end terminal lines 14tc, a plurality of second output-end terminal lines 14td, and a plurality of third output-end terminal lines 14te (see FIG. 14) provided so as to extend parallel to each other on the display area D side of the under-chip circuitry C; and a plurality of input-end terminal lines 14tf (see FIG. 6) provided so as to extend parallel to each other on the terminal section T side of the under-chip circuitry C. Here, each third output-end terminal line 14te is disposed adjacent to each first output-end terminal line 14tc and each second output-end terminal line 14td as shown in FIG. 14. Note that the third output-end terminal lines 14te are, similarly to the first output-end terminal lines 14tc and the second output-end terminal lines 14td, provided as the first wiring layer.

In addition, the organic EL display panel 50b includes, in the chip-mounting portion M of the frame area F: the plurality of first output terminals 18g provided as chip-use terminals on the display area D side so as to be aligned in a single row in the display area D side of the under-chip circuitry C along the longer side of the display area D side of the under-chip circuitry C; the plurality of second output terminals 18h provided as chip-use terminals on the terminal section T side so as to be aligned in a single row in the display area D side of the under-chip circuitry C along the longer side of the display area D side of the under-chip circuitry C; the plurality of third output terminals 18i (see FIG. 14) provided as chip-use terminals between the plurality of first output terminals 18g and the plurality of second output terminals 18h so as to be aligned in a single row in the display area D side of the under-chip circuitry C along the longer side of the display area D side of the under-chip circuitry C; and the plurality of input terminals 18j provided as chip-use terminals so as to be aligned in a single row in the terminal section T side of the under-chip circuitry C along the longer side of the terminal section T side of the under-chip circuitry C. Here, the plurality of first output terminals 18g, the plurality of third output terminals 18i, and the plurality of second output terminals 18h are repeatedly provided in the order of the first output terminals 18g, the third output terminals 18i, and the second output terminals 18h as shown in FIG. 14. Note that similarly to, for example, the first output terminals 18g and the second output terminals 18h, the third output terminals 18i are provided as the second wiring layer. In addition, the plurality of third output terminals 18i are stacked respectively on the plurality of third output-end terminal lines 14te and electrically connected respectively to the plurality of third output-end terminal lines 14te. Furthermore, similarly to the plurality of first output terminals 18j and the plurality of second output terminals 18h, the plurality of third output terminals 18i are provided in such a manner as to correspond to the plurality of bumps 61 on the back face of the integrated circuit chip 60 and electrically connected to the plurality of bumps 61 via the anisotropic conductive film 65.

In addition, the organic EL display panel 50b, in the chip-mounting portion M of the frame area F: chip support bodies Sc provided in an insular manner, one each in every gap between the plurality of first output terminals 18g and between the plurality of second output terminals 18h; and the chip support bodies Sb (see FIGS. 6 and 8) provided in an insular manner, one each in every gap between the plurality of input terminals 18j, as shown in FIG. 14. Note that no chip support bodies Sc are provided between the plurality of third output terminals 18i as shown in FIG. 14.

Similarly to the aforementioned chip support body Sa in accordance with the first embodiment, each chip support body Sc includes: a first inorganic insulating layer 15a made of the same material, and provided in the same layer, as the first interlayer insulating film 15; a second inorganic insulating layer 17a provided on the first inorganic insulating layer 15a and made of the same material, and provided in the same layer, as the second interlayer insulating film 17; and the organic insulating layer 19b provided on the second inorganic insulating layer 17a and made of the same material, and provided in the same layer, as the first planarization film 19a. Note that since the first output-end terminal lines 14tc and the first output terminals 18g, as well as the second output-end terminal lines 14td and the second output terminals 18h, are extended to both end portions of the chip support body Sc in terms of the width direction thereof, the integrated circuit chip 60 and the chip support bodies Sc are separated only by a smaller gap. This restrains warping of the panel at the first output terminals 18g and the second output terminals 18h in pressure bonding of the chip, which in turn enables restraining breakage of the first output terminals 18g, the second output terminals 18h, the first output-end terminal lines 14tc, and the second output-end terminal lines 14td. In addition, as shown in FIG. 14, since the display area D side of the chip support bodies Sc provided on the display area D side (toward the top of the drawing) is disposed outside the chip-mounting portion M (outside a peripheral end E of the integrated circuit chip 60), the integrated circuit chip 60 and the chip support bodies Sc are separated only by a small gap at sites where there are provided no bumps 61, which enables restraining warping of the panel in pressure bonding of the chip.

Note that the present embodiment, where the third output terminals 18i are separated from the first output terminals 18g and the second output terminals 18h by a relatively small distance, has disclosed, as an example, the organic EL display panel 50b in which no chip support body is provided between the plurality of third output terminals 18i. The organic EL display panel 50ba shown in FIG. 15 is also feasible. Specifically, in the organic EL display panel 50ba, the third output terminals 18i are separated from the first output terminals 18g and the second output terminals 18h by a relatively large distance, and there is provided a chip support body Sd between the plurality of third output terminals 18i. Here, the chip support body Sd is interconnected to a chip support body (Sd) provided between the plurality of first output terminals 18g and to a chip support body (Sd) provided between the plurality of second output terminals 18h, as shown in FIG. 15. Note that the present variation example has discussed, as an example, the chip support body Sd in which the portions between the plurality of third output terminals 18i are interconnected respectively to the portions between the plurality of first output terminals 18g and the portions between the plurality of second output terminals 18h. Alternatively, the portions between the plurality of third output terminals 18i may be separated respectively from the portions between the plurality of first output terminals 18g and the portions between the plurality of second output terminals 18h or may be interconnected respectively to the portions between of the plurality of first output terminals 18g or to the portions between the plurality of second output terminals 18h.

Similarly to the organic EL display device 70a in accordance with the first embodiment above, the organic EL display device in accordance with the present embodiment including the aforementioned organic EL display panel 50b is flexible and configured to display images by causing the light-emitting layer 3 in the organic EL layer 33 to emit light in a suitable manner in each subpixel P via the first TFT 9a, the second TFT 9b, and the third TFT 9c.

Note that the present embodiment has discussed, as an example, an organic EL display device including the organic EL display panel 50b provided with the output terminals 18g, 18h, and 18i having a 3-step structure in a plan view. Alternatively, an organic EL display device is also feasible that includes an organic EL display panel provided with output terminals having a 4-or more step structure in a plan view.

The organic EL display device including the organic EL display panel 50b in accordance with the present embodiment can be manufactured by the aforementioned method of manufacturing the organic EL display device 70a in accordance with the first embodiment, by changing the pattern shapes of the first wiring layer, the second wiring layer, the first inorganic insulating layer 15a, the second inorganic insulating layer 17a, and the organic insulating layer 19b.

As described above, in the organic EL display device including the organic EL display panel 50b in accordance with the present embodiment, in the chip-mounting portion M of the frame area F, the chip support bodies Sc are provided in an insular manner, one each in every gap between the plurality of first output terminals 18g and between the plurality of second output terminals 18h, and the chip support bodies Sb are provided in an insular manner, one each in every gap between the plurality of input terminals 18j. Therefore, the conductive particles 64 in the anisotropic conductive film 65 are transported by being extruded by the chip support bodies Sc and the chip support bodies Sb in the mounting step, so that the conductive particles 64 are relatively dense on the chip-use terminals of the first output terminals 18g, the second output terminals 18h, and the input terminals 18j and relatively sparse between the chip-use terminals. This renders the conductive particles 64 less likely to interconnect between the adjacent chip-use terminals, enabling restraining short-circuiting between the adjacent chip-use terminals due to interconnection of the conductive particles 64, which in turn enables restraining short-circuiting between the terminals on the chip-mounting portion M.

In addition, in the organic EL display device including the organic EL display panel 50b in accordance with the present embodiment, since the chip support bodies Sc and Sb are provided near the chip-use terminals of the plurality of first output terminals 18g, the plurality of second output terminals 18h, and the plurality of input terminals 18j in the chip-mounting portion M of the frame area F, the organic EL display panel 50b can be restrained from warping near the bumps 61 of the integrated circuit chip 60 in the mounting step. Hence, cracks are restrained from developing in the base coat film 11, the gate insulating film 13, the first interlayer insulating film 15, and the second interlayer insulating film 17 in the organic EL display panel 50b, and the first output-end terminal lines 14tc, the second output-end terminal lines 14td, the third output-end terminal lines 14te, and the input-end terminal lines 14tf, which are provided between the gate insulating film 13 and the first interlayer insulating film 15, can be restrained from breaking.

### Third Embodiment

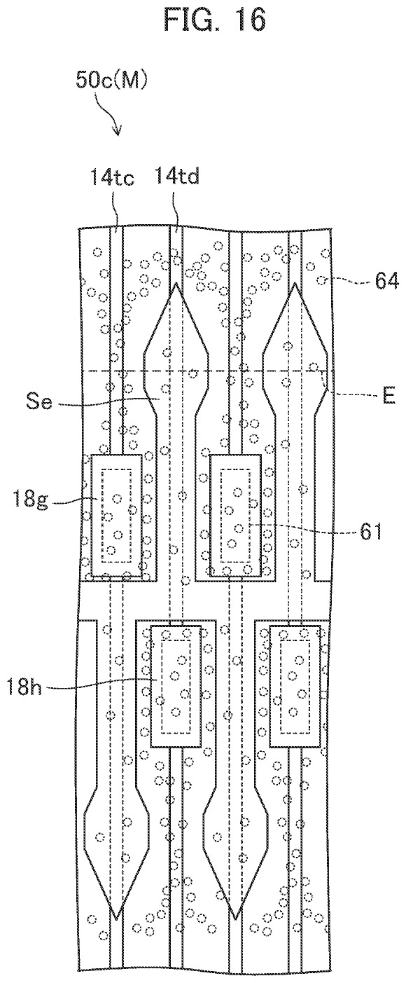

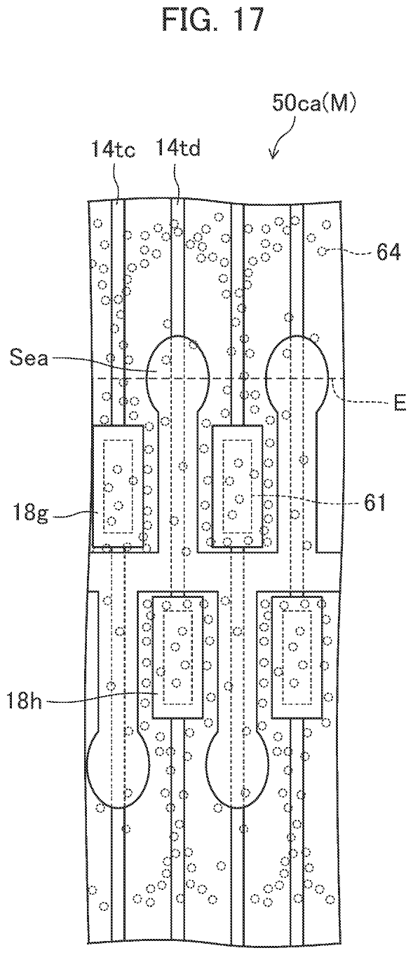

FIGS. 16 to 19 illustrate a third embodiment of the display device in accordance with the present invention. Here, FIG. 16 is a plan view, equivalent to FIG. 7, of the first output terminals 18g, the second output terminals 18h, and a chip support body Se in the chip-mounting portion M of the frame area F of an organic EL display panel 50c that is a part of an organic EL display device in accordance with the present embodiment. In addition, FIGS. 17, 18, and 19 are plan views, equivalent to FIG. 16, of an organic EL display panel 50ca, which is a first variation example of the organic EL display panel 50c, an organic EL display panel 50cb, which is a second variation example of the organic EL display panel 50c, and an organic EL display panel 50cc, which is a second variation example of the organic EL display panel 50c.

The first embodiment above discussed, as an example, the organic EL display device 70a including the organic EL display panel 50a provided with the chip support bodies having a constant width. The present embodiment discusses, as an example, an organic EL display device including the organic EL display panel 50c provided with a chip support body having a partially increased or decreased width.

Similarly to the organic EL display device 70a in accordance with the first embodiment above, the organic EL display device in accordance with the present embodiment includes: an organic EL display panel 50c; an integrated circuit chip 60 mounted to the chip-mounting portion M of the organic EL display panel 50c; and a flexible printed wiring board 55 mounted to the terminal section T of the organic EL display panel 50c.

Similarly to the organic EL display panel 50a in accordance with the first embodiment above, the organic EL display panel 50c has, for example, a rectangular display area D for displaying image3; and a frame area F shaped like a frame surrounding the display area D.

In addition, similarly to the organic EL display panel 50a in accordance with the first embodiment above, the organic EL display panel 50c includes: a flexible substrate layer 10; a TFT layer 30 on the flexible substrate layer 10; an organic EL element layer 40 on the TFT layer 30; and a sealing film 45 provided so as to cover the organic EL element layer 40.

In addition, similarly to the organic EL display panel 50a in accordance with the first embodiment above, the organic EL display panel 50c includes, in the chip-mounting portion M of the frame area F: under-chip circuitry C; a plurality of first output-end terminal lines 14tc and a plurality of second output-end terminal lines 14td provided so as to extend parallel to each other on the display area D side of the under-chip circuitry C; and a plurality of input-end terminal lines 14tf (see FIGS. 6 and 8) provided so as to extend parallel to each other on the terminal section T side of the under-chip circuitry C, as shown in FIG. 16.

In addition, referring to FIG. 16, similarly to the organic EL display panel 50a in accordance with the first embodiment above, the organic EL display panel 50c includes, in the chip-mounting portion M of the frame area F: the plurality of first output terminals 18g provided as chip-use terminals on the display area D side so as to be aligned in a single row in the display area D side of the under-chip circuitry C along the longer side of the display area D side of the under-chip circuitry C; the plurality of second output terminals 18h provided as chip-use terminals on the terminal section T side so as to be aligned in a single row in the display area D side of the under-chip circuitry C along the longer side of the display area D side of the under-chip circuitry C; and the plurality of input terminals 18j (see FIGS. 6 and 8) provided as chip-use terminals on the terminal section T side of the under-chip circuitry C so as to be aligned in a single row along the longer side of the terminal section T side of the under-chip circuitry C.

In addition, referring to FIG. 16, the organic EL display panel 50c includes, in the chip-mounting portion M of the frame area F: the chip support body Se provided like double-sided comb teeth, but in a single piece, between the plurality of first output terminals 18g and between the plurality of second output terminals 18h; and chip support bodies Sb (see FIGS. 6 and 8) in an insular manner, one each in every gap between the plurality of input terminals 18j.

Similarly to the chip support body Sa in accordance with the first embodiment above, the chip support body Se includes: a first inorganic insulating layer 15a made of the same material, and provided in the same layer, as the first interlayer insulating film 15; a second inorganic insulating layer 17a provided on the first inorganic insulating layer 15a and made of the same material, and provided in the same layer, as the second interlayer insulating film 17; and an organic insulating layer 19b provided on the second inorganic insulating layer 17a and made of the same material, and provided in the same layer, as the first planarization film 19a. Note that since the first output-end terminal lines 14tc and the first output terminals 18g, as well as the second output-end terminal lines 14td and the second output terminals 18h, are extended to both end portions of the chip support body Se in terms of the width direction thereof, the integrated circuit chip 60 and the chip support body Se are separated only by a small gap. This restrains warping of the panel at the first output terminals 18g and the second output terminals 18h in pressure bonding of the chip, which in turn enables restraining breakage of the first output terminals 18g, the second output terminals 18h, the first output-end terminal lines 14tc, and the second output-end terminal lines 14td. In addition, as shown in FIG. 16, since the display area D side of the chip support body Se (toward the top of the drawing) is disposed outside the chip-mounting portion M (outside a peripheral end E of the integrated circuit chip 60), and this outside portion is increased in width at the peripheral end E of the integrated circuit chip 60, the integrated circuit chip 60 and the chip support body Se are separated only by a small gap at sites where there are provided no bumps 61, which enables further restraining warping of the panel in pressure bonding of the chip. Furthermore, as shown in FIG. 16, since the display area D side of the chip support body Se (toward the top of the drawing) and the terminal section T side of the chip support body Se (toward the bottom of the drawing) are shaped like a triangular-based pyramid so as to taper off toward the tip end, a discharge port for the resin material 63 of the anisotropic conductive film 65 used in the mounting step is increased in width, which allows for an easy flow of the resin material 63. Therefore, the conductive particles 64 in the anisotropic conductive film 65 are dispersed, enabling further restraining short-circuiting between the adjacent chip-use terminals due to interconnection of the conductive particles 64.

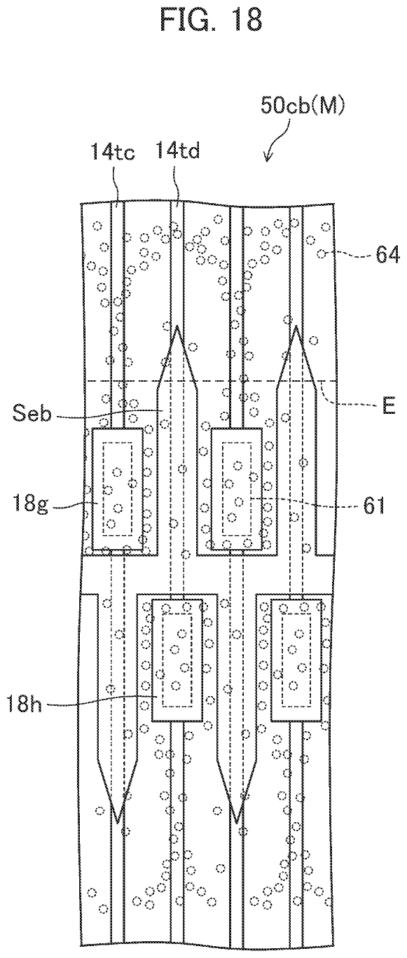

Note that the present embodiment has disclosed, as an example, the organic EL display panel 50c including the chip support body Se that temporarily increases in width at the peripheral end E of the integrated circuit chip 60 before tapering off. Alternatively, the organic EL display panel 50ca including a chip support body Sea shown in FIG. 17, the organic EL display panel 50cb including a chip support body Seb shown in FIG. 18, and the organic EL display panel 50cc including a chip support body Sec shown in FIG. 18 are also feasible.

As shown in FIG. 17, in the organic EL display panel 50ca, since the display area D side of the chip support body Sea (toward the top of the drawing) is disposed outside the chip-mounting portion M (outside the peripheral end E of the integrated circuit chip 60), and this outside portion is increased in width at the peripheral end E of the integrated circuit chip 60, the integrated circuit chip 60 and the chip support body Sea are separated only by a small gap at sites where there are provided no bumps 61, which enables further restraining warping of the panel in pressure bonding of the chip. Here, the display area D side (toward the top of the drawing) and the terminal section T side (toward the bottom of the drawing) of the chip support body Sea are shaped generally like a semicircle sphere so as to taper off toward the tip end, as shown in FIG. 17.

In the organic EL display panel 50cb, as shown in FIG. 18, the display area D side of the chip support body Seb (toward the top of the drawing) is disposed outside the chip-mounting portion M (outside the peripheral end E of the integrated circuit chip 60), and this outside portion is shaped like a triangular-based pyramid so as to taper off toward the tip end. Here, as shown in FIG. 18, since the display area D side (toward the top of the drawing) and the terminal section T side (toward the bottom of the drawing) of the chip support body Seb are shaped like a triangular-based pyramid so as to taper off toward the tip end, a discharge port for the resin material 63 of the anisotropic conductive film 65 used in the mounting step is increased in width, which allows for an easy flow of the resin material 63. Therefore, the conductive particles 64 in the anisotropic conductive film 65 are dispersed, enabling further restraining short-circuiting between the adjacent chip-use terminals due to interconnection of the conductive particles 64.

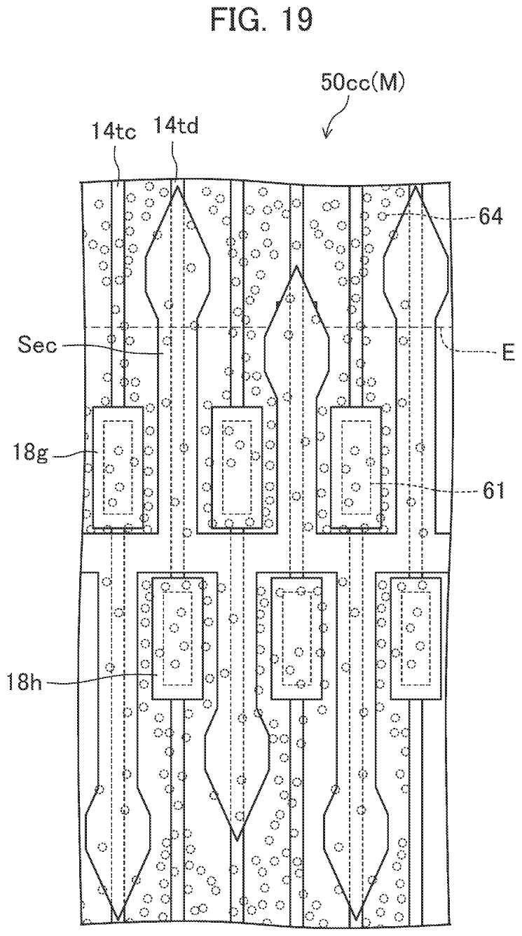

In the organic EL display panel 50cc, as shown in FIG. 19, the display area D side (toward the top of the drawing) of the chip support body Sec is disposed outside the chip-mounting portion M (outside the peripheral end E of the integrated circuit chip 60), and this outside portion is shaped like a triangular-based pyramid so as to taper off toward the tip end. Here, as shown in FIG. 18, since the display area D side (toward the top of the drawing) and the terminal section T side (toward the bottom of the drawing) of the chip support body Sec have the tip ends thereof alternately disposed in a staggered pattern in a direction along the longer side of the chip-mounting portion M, the discharge port for the resin material 63 of the anisotropic conductive film 65 used in the mounting step is disposed oblique to the longer side of the chip-mounting portion M and increased in width, which allows for an easy flow of the resin material 63. Therefore, the conductive particles 64 in the anisotropic conductive film 65 are dispersed, enabling further restraining short-circuiting between the adjacent chip-use terminals due to interconnection of the conductive particles 64.

Similarly to the organic EL display device 70a in accordance with the first embodiment above, the organic EL display device in accordance with the present embodiment including the aforementioned organic EL display panel 50c is flexible and configured to display images by causing the light-emitting layer 3 in the organic EL layer 33 to emit light in a suitable manner in each subpixel P via the first TFT 9a, the second TFT 9b, and the third TFT 9c.

The organic EL display device including the organic EL display panel 50c in accordance with the present embodiment can be manufactured by the aforementioned method of manufacturing the organic EL display device 70a in accordance with the first embodiment, by changing the pattern shapes of the first inorganic insulating layer 15a, the second inorganic insulating layer 17a, and the organic insulating layer 19b.

As described above, in the organic EL display device including the organic EL display panel 50c in accordance with the present embodiment, in the chip-mounting portion M of the frame area F, the chip support body Se is provided like double-sided comb teeth between the plurality of first output terminals 18g and between the plurality of second output terminals 18h, and the chip support bodies Sb are provided in an insular manner, one each in every gap between the plurality of input terminals 18j. Therefore, the conductive particles 64 in the anisotropic conductive film 65 are transported by being extruded by the chip support body Se and the chip support bodies Sb in the mounting step, so that the conductive particles 64 are relatively dense on the chip-use terminals of the first output terminals 18g, the second output terminals 18h, and the input terminals 18j and relatively sparse between the chip-use terminals. This renders the conductive particles 64 less likely to interconnect between the adjacent chip-use terminals, enabling restraining short-circuiting between the adjacent chip-use terminals due to interconnection of the conductive particles 64, which in turn enables restraining short-circuiting between the terminals on the chip-mounting portion M.

In addition, in the organic EL display device including the organic EL display panel 50c in accordance with the present embodiment, since the chip support bodies Se and Sb are provided near the chip-use terminals of the plurality of first output terminals 18g, the plurality of second output terminals 18h, and the plurality of input terminals 18j in the chip-mounting portion M of the frame area F, the organic EL display panel 50c can be restrained from warping near the bumps 61 of the integrated circuit chip 60 in the mounting step. Hence, cracks are restrained from developing in the base coat film 11, the gate insulating film 13, the first interlayer insulating film 15, and the second interlayer insulating film 17 in the organic EL display panel 50c, and the first output-end terminal lines 14tc, the second output-end terminal lines 14td, and the input-end terminal lines 14tf, which are provided between the gate insulating film 13 and the first interlayer insulating film 15, can be restrained from breaking.

### Fourth Embodiment

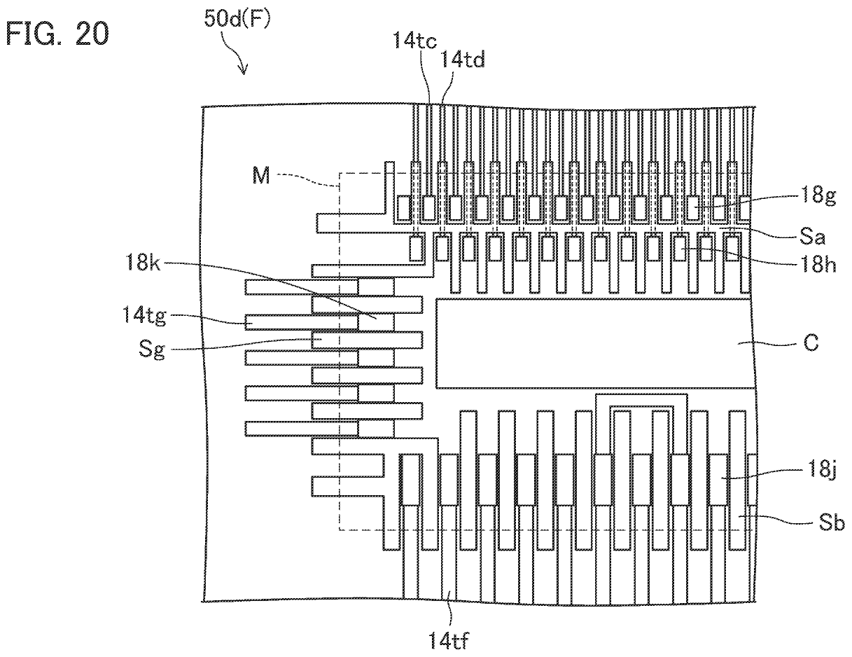

FIG. 20 is a diagram illustrating a fourth embodiment of a display device in accordance with the present invention. Here, FIG. 20 is an enlarged plan view, equivalent to FIG. 6, of a chip-mounting portion M in a frame area F of an organic EL display panel 50d in an organic EL display device in accordance with the present embodiment.

The first embodiment above discussed, as an example, the organic EL display device 70a including the organic EL display panel 50a provided with chip-use terminals along a longer side of the chip-mounting portion M. The present embodiment discusses, as an example, an organic EL display device including the organic EL display panel 50d provided also with chip-use terminals along a shorter side of the chip-mounting portion M.

Similarly to the organic EL display device 70a in accordance with the first embodiment above, the organic EL display device in accordance with the present embodiment includes: the organic EL display panel 50d; the integrated circuit chip 60 mounted to the chip-mounting portion M of the organic EL display panel 50d; and the flexible printed wiring board 55 mounted to the terminal section T of the organic EL display panel 50d.

Similarly to the organic EL display panel 50a in accordance with the first embodiment above, the organic EL display panel 50d has, for example: a rectangular display area D for displaying images; and a frame area F shaped like a frame surrounding the display area D.

In addition, similarly to the organic EL display panel 50a in accordance with the first embodiment above, the organic EL display panel 50d includes: a flexible substrate layer 10; a TFT layer 30 on the flexible substrate layer 10; an organic EL element layer 40 on the TFT layer 30; and a sealing film 45 provided so as to cover the organic EL element layer 40.

In addition, as shown in FIG. 20, the organic EL display panel 50d includes, in the chip-mounting portion M of the frame area F: under-chip circuitry C; a plurality of first output-end terminal lines 14tc and a plurality of second output-end terminal lines 14td provided so as to extend parallel to each other on the display area D side of the under-chip circuitry C; a plurality of input-end terminal lines 14tf provided so as to extend parallel to each other on the terminal section T side of the under-chip circuitry C; and a plurality of shorter-side terminal lines 14tg provided so as to extend parallel to each other on the left side (in the drawing) of the under-chip circuitry C.

In addition, as shown in FIG. 20, the organic EL display panel 50d includes, in the chip-mounting portion M of the frame area F: a plurality of first output terminals 18g provided as chip-use terminals on the display area D side so as to be aligned in a single row in the display area D side of the under-chip circuitry C along a longer side of the display area D side of the under-chip circuitry C; a plurality of second output terminals 18h provided as chip-use terminals on the terminal section T side so as to be aligned in a single row along a longer side of the display area D side of the under-chip circuitry C on the display area D side of the under-chip circuitry C; a plurality of input terminals 18j provided as chip-use terminals so as to be aligned in a single row along a longer side of the terminal section T side of the under-chip circuitry C on the terminal section T side of the under-chip circuitry C; and a plurality of shorter-side terminals 18k provided as chip-use terminals so as to be aligned in a single row along a shorter side of the chip-mounting portion M on the left side (in the drawing) of the under-chip circuitry C.

In addition, as shown in FIG. 20, the organic EL display panel 50d includes, in the chip-mounting portion M of the frame area F: a chip support body Sa provided like double-sided comb teeth, but in a single piece, between the plurality of first output terminals 18g and between the plurality of second output terminals 18h; chip support bodies Sb in an insular manner, one each in every gap between the plurality of input terminals 18j; and chip support bodies Sg in an insular manner, one each in every gap between the plurality of shorter-side terminals 18k.

Similarly to the chip support body Sa in accordance with the first embodiment, each chip support body Sg includes: a first inorganic insulating layer 15a made of the same material, and provided in the same layer, as the first interlayer insulating film 15; a second inorganic insulating layer 17a provided on the first inorganic insulating layer 15a and made of the same material, and provided in the same layer, as the second interlayer insulating film 17; and an organic insulating layer 19b provided on the second inorganic insulating layer 17a and made of the same material, and provided in the same layer, as the first planarization film 19a. Note that since the shorter-side terminal lines 14tg and the shorter-side terminals 18k are extended to both end portions of the chip support bodies Sg in terms of the width direction thereof, the integrated circuit chip 60 and the chip support bodies Sg are separated only by a small gap. This restrains warping of the panel at the shorter-side terminals 18k in pressure bonding of the chip, which in turn enables restraining breakage of the shorter-side terminals 18k and shorter-side terminal lines 14t. In addition, as shown in FIG. 20, since among the plurality of chip support bodies Sg, the chip support body Sg on the display area D side (toward the top of the drawing) and the chip support body Sg on the terminal section T side (toward the bottom of the drawing) are provided as a single piece respectively with the chip support body Sa and the chip support body Sb. Note that even when adjacent chip support bodies are provided as a single piece, it is ensured that the resin material 63 can flow sufficiently if there is at least one site that provides a discharge port for the resin material 63 for the anisotropic conductive film 65 used in the mounting step.

Similarly to the organic EL display device 70a in accordance with the first embodiment above, the organic EL display device in accordance with the present embodiment including the aforementioned organic EL display panel 50d is flexible and configured to display images by causing the light-emitting layer 3 in the organic EL layer 33 to emit light in a suitable manner in each subpixel P via the first TFT 9a, the second TFT 9b, and the third TFT 9c.

The organic EL display device including the organic EL display panel 50d in accordance with the present embodiment can be manufactured by the aforementioned method of manufacturing the organic EL display device 70a in accordance with the first embodiment, by changing the pattern shapes of the first wiring layer, the second wiring layer, the first inorganic insulating layer 15a, the second inorganic insulating layer 17a, and the organic insulating layer 19b.

As described above, in the organic EL display device including the organic EL display panel 50d in accordance with the present embodiment, in the chip-mounting portion M of the frame area F, the chip support body Sa is provided like double-sided comb teeth between the plurality of first output terminals 18g and the plurality of second output terminals 18h, the chip support bodies Sb are provided in an insular manner, one each in every gap between the plurality of input terminals 18j, and the chip support bodies Sg are provided in an insular manner, one each in every gap between the plurality of shorter-side terminals 18k. Therefore, the conductive particles 64 in the anisotropic conductive film 65 are transported by being extruded by the chip support bodies Sa, Sb, and Sg in the mounting step, so that the conductive particles 64 are relatively dense on the chip-use terminals of the first output terminals 18g, the second output terminals 18h, the input terminals 18j, and the shorter-side terminals 18k and relatively sparse between the chip-use terminals. This renders the conductive particles 64 less likely to interconnect between the adjacent chip-use terminals, enabling restraining short-circuiting between the adjacent chip-use terminals due to interconnection of the conductive particles 64, which in turn enables restraining short-circuiting between the terminals on the chip-mounting portion M.

In addition, in the organic EL display device including the organic EL display panel 50d in accordance with the present embodiment, since the chip support bodies Sa, Sb, and Sg are provided near the chip-use terminals of the plurality of first output terminals 18g, the plurality of second output terminals 18h, the plurality of input terminals 18j, and the plurality of shorter-side terminals 18k in the chip-mounting portion M the frame area F, the organic EL display panel 50d can be restrained from warping near the bumps 61 of the integrated circuit chip 60 in the mounting step. Hence, cracks are restrained from developing in the base coat film 11, the gate insulating film 13, the first interlayer insulating film 15, and the second interlayer insulating film 17 in the organic EL display panel 50d, and the first output-end terminal lines 14tc, the second output-end terminal lines 14td, the input-end terminal lines 14tf, and the shorter-side terminal lines 14tg, which are provided between the gate insulating film 13 and the first interlayer insulating film 15, can be restrained from breaking.

### Other Embodiments

The foregoing embodiments have discussed examples where the organic EL display device includes the organic EL display panel 50a, 50b, 50c, and 50d. The present invention is equally applicable to, for example, organic EL display devices constructed by combining the features of any of these embodiments in a suitable manner.

In addition, the foregoing embodiments have discussed examples where the organic EL display device includes bumps that are arranged in a regular pattern parallel or perpendicular to a longer side and a shorter side of the integrated circuit chip. The present invention is not at all limited to these examples and equally applicable to, for example, organic EL display devices including bumps that are arranged in a pattern oblique to a longer side and a shorter side of the integrated circuit chip.

In addition, the foregoing embodiments have discussed examples where the organic EL layer has a 5-layered structure that includes a hole injection layer, a hole transport layer, a light-emitting layer, an electron transport layer, and an electron injection layer. Alternatively, the organic EL layer may have, for example, a 3-layered structure that includes a hole injection and transport layer, a light-emitting layer, and an electron transport and injection layer.

In addition, the foregoing embodiments have discussed examples where the organic EL display device includes a first electrode as an anode and a second electrode as a cathode. The present invention is equally applicable to organic EL display devices in which the layered structure of the organic EL layer is reversed, to include a first electrode as a cathode and a second electrode as an anode.

In addition, the foregoing embodiments have discussed examples where the organic EL display device includes TFTs each having a drain electrode connected to the first electrode. The present invention is equally applicable to organic EL display devices including TFTs each having a “source electrode” connected to the first electrode.

In addition, the foregoing embodiments have discussed organic EL display devices as an example of the display device. The present invention is equally applicable to display devices including a plurality of current-driven light-emitting elements, for example, applicable to display devices including QLEDs (quantum-dot light-emitting diodes) which are light-emitting elements using a quantum-dot-containing layer.

### INDUSTRIAL APPLICABILITY

As described above, the present invention is useful in flexible display devices.

### REFERENCE SIGNS LIST

D Display Area
E Extension Line
F Frame Area
M Chip-mounting Portion
P Subpixel
Sa, Sb, Sc, Sd, Sg, Saa, Se, Sea, Seb, Sec Chip Support Body
T Terminal Section
10 Flexible Substrate Layer
13 Gate Insulating Film
14a, 14b Gate Electrode (First Wiring Layer)
14c Underlying Conductive Layer (First Wiring Layer)
14g Gate Line (First Wiring Layer)
14e Light-emission Control Line (First Wiring Layer)
14tc, 14td, 14te Output-end Terminal Line
14tf Input-end Terminal Line
15 First Interlayer Insulating Film
15a First Inorganic Insulating Layer
17 Second Interlayer Insulating Film
17A Second Inorganic Insulating Layer
18a, 18c Source Electrode (Second Wiring Layer)
18b, 18d Drain Electrode (Second Wiring Layer)
18f Source Line (Second Wiring Layer)
18g First Output Terminal (Chip-use Terminal)
18h Second Output Terminal (Chip-use Terminal)
18i Third Output Terminal (Chip-use Terminal)
18j Input Terminal (Chip-use Terminal)
18k Shorter-side Terminal
19a First Planarization Film
19b Organic Insulating Layer, First Organic Insulating Layer
21a Second Planarization Film
21b Second Organic Insulating Layer
30 TFT Layer (Thin Film Transistor Layer)
35 Organic EL Element (Organic Electroluminescence Element, Light-emitting Element)
40 Organic EL Element Layer (Light-emitting Element Layer)
41 First Inorganic Sealing Film
42 Organic Sealing Film
43 Second Inorganic Sealing Film
45 Sealing Film
50a, 50aa, 50b, 50ba, 50c, 50ca, 50cb, 50cc, 50d Organic EL Display Panel
60 Integrated Circuit Chip
61 Bump
64 Conductive Particle
65 Anisotropic Conductive Film
70a, 70aa Organic EL Display Device

1. A display device comprising:
a flexible substrate layer;
a thin film transistor layer on the flexible substrate layer; and
a light-emitting element layer on the thin film transistor layer in such a manner as to correspond to a plurality of subpixels disposed in a display area, the light-emitting element layer including a plurality of light-emitting elements, wherein
a frame area is provided surrounding the display area,
a terminal section is provided extending in a single direction on an end portion of the frame area,
a chip-mounting portion is provided between the display area and the terminal section, the chip-mounting portion being rectangular in a plan view and having a longer side extending in the direction in which the terminal section extends,
a plurality of chip-use terminals are provided in a single row on the chip-mounting portion, and a plurality of terminal lines are provided extending parallel to each other in such a manner as to correspond to the plurality of chip-use terminals and being electrically connected respectively to the plurality of chip-use terminals, and
a chip support body is provided between the plurality of chip-use terminals on the chip-mounting portion.

2. The display device according to claim 1, wherein
as the plurality of chip-use terminals, a plurality of input terminals are provided in a single row along a longer side on the terminal-section side of the chip-mounting portion, and
each chip support body is provided in an insular manner between the plurality of input terminals.

3. The display device according to claim 2, wherein the terminal-section side of the chip support body provided with respect to the plurality of input terminals is disposed outside the chip-mounting portion.

4. The display device according to claim 1, wherein
as the plurality of chip-use terminals, a plurality of output terminals are provided in a single row along a longer side on a display-area side of the chip-mounting portion,
the plurality of output terminals include:
a plurality of first output terminals provided in a single row on the display-area side; and
a plurality of second output terminals provided in a single row on the terminal-section side,
the plurality of first output terminals and the plurality of second output terminals are alternately provided in a staggered pattern along the longer side of the chip-mounting portion, and
the chip support body is provided like double-sided comb teeth, but in a single piece, between the plurality of first output terminals and between the plurality of second output terminals.

5. The display device according to claim 4, wherein a display-area side of the chip support body provided with respect to the plurality of first output terminals and the plurality of second output terminals is disposed outside the chip-mounting portion.

6. The display device according to claim 3, wherein a portion outside the chip-mounting portion on which the chip support body is provided has a large width on a peripheral end of the chip-mounting portion.

7. The display device according to claim 3, wherein a portion outside the chip-mounting portion on which the chip support body is provided is tapered toward a tip end.

8. The display device according to claim 3, wherein a tip end of a portion outside the chip-mounting portion on which the chip support body is provided is alternately provided in a staggered pattern along the longer side of the chip-mounting portion.

9. The display device according to claim 1, wherein
the thin film transistor layer includes a gate insulating film, a first wiring layer, an interlayer insulating film, a second wiring layer, and a planarization film, all of which are sequentially stacked on the flexible substrate layer,
the chip-use terminal is provided on the plurality of terminal lines made of a same material, and provided in a same layer, as the first wiring layer and is made of a same material, and provided in a same layer, as the second wiring layer,
the chip support body includes: an inorganic insulating layer made of a same material, and provided in a same layer, as the interlayer insulating film; and an organic insulating layer provided on the inorganic insulating layer and made of a same material, and provided in a same layer, as the planarization film, and
the organic insulating layer is thicker in a central portion in terms of a width direction than in both end portions in terms of the width direction.

10. The display device according to claim 9, wherein
the planarization film includes: a first planarization film on the flexible substrate layer side; and a second planarization film opposite the flexible substrate layer,
the organic insulating layer includes: a first organic insulating layer made of a same material, and provided in a same layer, as the first planarization film; and a second organic insulating layer provided on the first organic insulating layer and made of a same material, and provided in a same layer, as the second planarization film, and
the second organic insulating layer has a smaller width than the first organic insulating layer.

11. The display device according to claim 9, wherein the plurality of terminal lines and the chip-use terminal are extended to both end portions of the chip support body in terms of a width direction.

12. The display device according to claim 1, wherein
as the plurality of chip-use terminals, a plurality of output terminals are provided in a single row along a longer side on a display-area side of the chip-mounting portion,
the plurality of output terminals include:
a plurality of first output terminals provided in a single row on the display-area side;
a plurality of second output terminals provided in a single row on the terminal-section side; and
a plurality of third output terminals provided in a single row between the plurality of first output terminals and the plurality of second output terminals, and
the plurality of first output terminals, the plurality of third output terminals, and the plurality of second output terminals are repeatedly provided in an order of the plurality of first output terminals, the plurality of third output terminals, and the plurality of second output terminal along the longer side of the chip-mounting portion.

13. The display device according to claim 12, wherein the chip support body is respectively provided between the plurality of first output terminals and between the plurality of second output terminals.

14. The display device according to claim 13, wherein the chip support body is not provided between the plurality of third output terminals.

15. The display device according to claim 12, wherein
the chip support body is respectively provided between the plurality of first output terminals, between the plurality of second output terminals, and between the plurality of third output terminals, and
the chip support body provided between the plurality of third output terminals is respectively interconnected to the corresponding chip support body provided between the plurality of first output terminals and the corresponding chip support body provided between the plurality of second output terminals.

16. The display device according to claim 1 wherein
as the plurality of chip-use terminals, a plurality of shorter-side terminals are provided in a single row along a shorter side of the chip-mounting portion on the chip-mounting portion, and
each chip support body is provided in an insular manner between the plurality of shorter-side terminals.

17. The display device according to claim 1, wherein an integrated circuit chip is mounted to the chip-mounting portion via an anisotropic conductive film.

18. The display device according to claim 17, wherein
a plurality of bumps are provided on a back face of the integrated circuit chip in such a manner as to correspond to the plurality of chip-use terminals,
the anisotropic conductive film contains conductive particles, and
the plurality of bumps and the plurality of chip-use terminals are electrically respectively connected via the conductive particles.

19. The display device according to claim 1, further comprising a sealing film including a first inorganic sealing film, an organic sealing film, and a second inorganic sealing film, all of which are sequentially stacked, so as to cover the light-emitting element layer.

20. The display device according to claim 1, wherein each of the plurality of light-emitting elements is an organic electroluminescence element.
